(19) United States
(12) Patent Application Publication
(10) Pub. No.: US 2024/0321646 A1
(43) Pub. Date: Sep. 26, 2024

(54) THRESHOLD VOLTAGE TUNING USING A MULTIPLE DIPOLE LOOP PROCESS FOR CFET DEVICES

(71) Applicant: Taiwan Semiconductor Manufacturing Company, Ltd., Hsin-Chu (TW)

(72) Inventors: Ming-Ho Lin, Taipei City (TW); Yao-Teng Chuang, Hsinchu (TW); Cheng-Hao Hou, Hsinchu City (TW); Tsung-Da Lin, Hsinchu (TW); Da-Yuan Lee, Hsinchu County (TW); Chi On Chui, Hsinchu City (TW)

(21) Appl. No.: 18/332,054

(22) Filed: Jun. 9, 2023

(51) Int. Cl. H01L 21/8238; H01L 21/822; H01L 27/092; H01L 29/06; H01L 29/423; H01L 29/49; H01L 29/66; H01L 29/775

(52) U.S. Cl. CPC H01L 21/823857; H01L 21/8221; H01L 21/823807; H01L 21/823814; H01L 21/823878; H01L 27/0922; H01L 29/0673; H01L 29/42392; H01L 29/4908; H01L 29/66439; H01L 29/66545; H01L 29/775

(57) ABSTRACT

A method of forming a semiconductor device includes forming a CFET structure having a bottom gate region having a first plurality of gate dielectric layers wrapping around a first plurality of channels and a top gate region having a second plurality of gate dielectric layers wrapping around a second plurality of channels. The method includes performing a first dipole loop process to drive first dipole dopants into the first plurality of gate dielectric layers and performing a second dipole loop process to drive second dipole dopants into the second plurality of gate dielectric layers. And after performing the first and second dipole loop processes, the method includes depositing a gate metal over the first and second plurality of gate dielectric layers.

### BACKGROUND

The present disclosure relates to an integrated circuit (IC) structure and a method of making the same. Especially, the IC structure includes a transistor structure having multiple vertically stacked gate-all-around transistors, each of which includes multiple vertically stacked nanowires or nanosheets as channels. More specifically, the IC structure includes a complementary field-effect transistor (CFET) structure and the method of making the CFET. The CFET may include N-type FETs vertically over P-type FETs or P-type FETs vertically over the N-type FET.

For advanced technology such as CFETS, multi threshold voltage (Vt) devices are necessary to provide high speed or low standby power devices. Existing structure and methods include varying metal gate thicknesses or metal gate materials to create multi Vt offerings. However, relying on metal gate thickness and different metal materials in advanced technologies such as CFETs becomes difficult due to critical dimension scaling.

Therefore, while existing threshold voltage tuning for IC devices are generally adequate for their intended purposes, they are not satisfactory in all aspects.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 illustrates a cross-sectional view of a monolithic CFET semiconductor device having multi Vt offerings, according to various aspects of the present disclosure.

FIGS. 2A-2B is a flow chart of a method to form a monolithic CFET semiconductor device having multi Vt offerings, in portion or in entirety, according to various aspects of the present disclosure.

FIGS. 3-13 illustrate cross-sectional views of a monolithic CFET semiconductor device having multi Vt offerings at intermediate stages of fabrication and processed in accordance with the method of FIGS. 2A-2B according to an embodiment of the present disclosure.

FIG. 14A illustrates an x cross-sectional view of a first CFET gate region before performing a first dipole loop process according to an embodiment of the present disclosure.

FIG. 14B illustrates a y cross-sectional view of a first CFET channel region before performing a first dipole loop process according to an embodiment of the present disclosure.

FIG. 15 is a flow chart of a method to perform a first dipole loop process according to an embodiment of the present disclosure.

FIG. 16 illustrates y cross-sectional views of a first CFET channel region at intermediate stages of fabrication and processed in accordance with the method of FIG. 15 according to an embodiment of the present disclosure.

FIG. 17 illustrates y cross-sectional views of a first CFET channel region after performing a first dipole loop process one or more times in accordance with the method of FIG. 15 according to an embodiment of the present disclosure.

FIG. 18A illustrates an x cross-sectional view of a first CFET gate region after performing a first dipole loop process according to an embodiment of the present disclosure.

FIG. 18B illustrates a y cross-sectional view of a first CFET channel region after performing a first dipole loop process according to an embodiment of the present disclosure.

FIG. 19 is a flow chart of a method to perform a second dipole loop process according to an embodiment of the present disclosure.

FIG. 20 illustrates y cross-sectional views of a first CFET channel region at intermediate stages of fabrication and processed in accordance with the method of FIG. 19 according to an embodiment of the present disclosure.

FIG. 21 illustrates y cross-sectional views of a first CFET channel region after performing a second dipole loop process one or more times in accordance with the method of FIG. 19 according to an embodiment of the present disclosure.

FIG. 22A illustrates an x cross-sectional view of a first CFET gate region after performing a second dipole loop process according to an embodiment of the present disclosure.

FIG. 22B illustrates a y cross-sectional view of a first CFET channel region after performing a second dipole loop process according to an embodiment of the present disclosure.

FIG. 23A illustrates an x cross-sectional view of a first CFET gate region after forming a metal gate electrode according to an embodiment of the present disclosure.

FIGS. 23B and 23B-1 illustrate y cross-sectional views of respective first CFET channel regions after forming a metal gate electrode according to an embodiment of the present disclosure.

FIGS. 24A and 24B illustrate y cross-sectional views of respective first CFET channel regions after forming a metal gate electrode according to additional embodiments of the present disclosure.

FIG. 25 is an exemplary diagram showing a first dipole patterning process that is used when performing the first and/or second dipole loop processes.

FIG. 26 is an exemplary diagram showing a second dipole patterning process that is used when performing the first and/or second dipole loop processes.

FIG. 27 illustrates a cross-sectional view of a sequential CFET semiconductor device having multi Vt offerings, according to various aspects of the present disclosure.

FIGS. 28A-28B is a flow chart of a method to form a sequential CFET semiconductor device having multi Vt offerings, in portion or in entirety, according to various aspects of the present disclosure.

FIGS. 29-41 illustrate cross-sectional views of a sequential CFET semiconductor device having multi Vt offerings at intermediate stages of fabrication and processed in accordance with the method of FIGS. 28A-28B according to an embodiment of the present disclosure.

FIG. 42A is a flow chart of a method to perform a first dipole loop process according to an embodiment of the present disclosure.

FIG. 42B is a flow chart of a method to perform a second dipole loop process according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +1-15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to CFET semiconductor devices having multiple threshold voltage (Vt) offerings for optimized performance in targeted applications (e.g., high speed or low standby power devices). However, due to the complexity of a CFET structure and to address the CFET critical dimension limitations, integrating dipoles become more important for “volume-less” Vt tuning. That is, instead of increasing the volume dimension of a metal gate structure for Vt tuning, dipoles are driven into the gate structures without increasing the volume of the metal gate structure. For enhanced performance and device flexibility, a tunable N-type dipole (such as lanthanum oxide) and a tunable P-type dipole (such as zinc oxide) are combined with multi patterning on CFET for continuously variable Vt Tuning. The combination of multi-patterning (dipole patterning) and multi-annealing (dipole loops) on CFET with n-type and p-type specific dipoles offer volume-less multi-Vt devices that satisfy critical dimension limitations and provide large range of threshold voltages. For example, different CFET gate structures of the same size may be doped differently to have different threshold voltages. For another example, NFET and PFET gate regions of a same CFET may be doped differently to have different threshold voltages. Yet in another example, gate regions within a same NFET or PFET of a CFET may be doped differently from channel to channel, offering different threshold activation voltages for a single NFET or PFET.

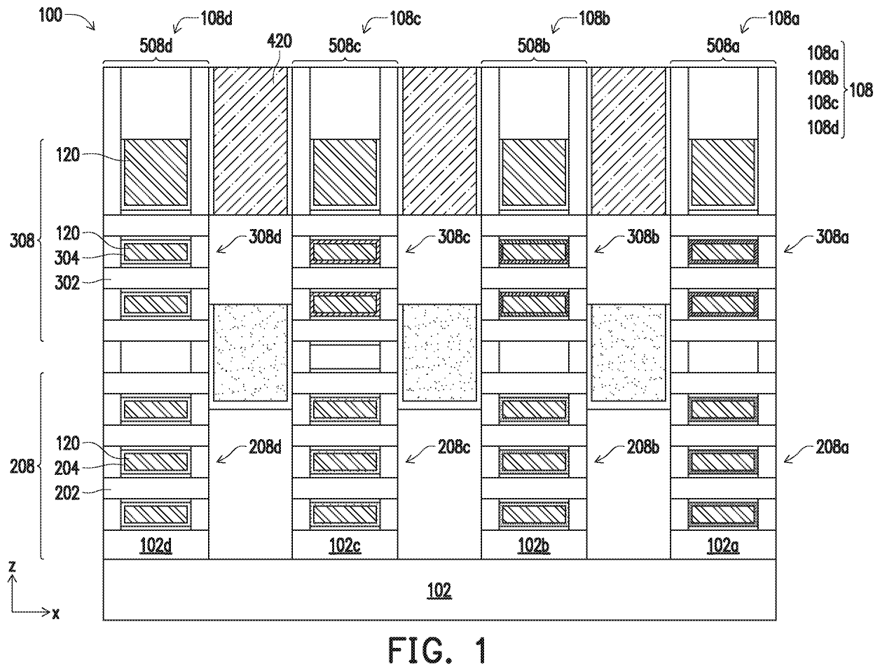

FIG. 1 illustrates a cross-sectional view of a monolithic CFET semiconductor device 100 having multi Vt offerings. As will be explained in more detail below, the multi Vt offering is effectuated through iteratively doping respective gate dielectric layers 204 and/or 304 in different CFET gate regions 108. As an exemplary embodiment, FIG. 1 shows four CFET gate regions 108a, 108b, 108c, and 108d over respective channel regions 102a, 102b, 102c, and 102d protruding from a substrate 102. Stacks of semiconductor channels 202 and/or 302 are disposed over respective channel regions 102a, 102b, 102c, and 102d. In each of the CFET gate regions 108, the semiconductor channels 202/302 are wrapped around and interposed by respective CFET metal gate structures 508a, 508b, 508c, and 508d, each having gate dielectric layers 204/304 and a metal gate electrode 120. A top portion of the metal gate electrode 120 is disposed over the topmost channels 302 of each stack.

Still referring to FIG. 1, the CFET gate regions 108 include NFET gate regions 308 over PFET gate regions 208. More specifically, each of the metal gate structures 508a-508d includes a NFET gate region 308 over a PFET gate region 208. For example, an NFET gate region 308a is over a PFET gate region 208a for the CFET metal gate structure 508a; an NFET gate region 308b is over a PFET gate region 208b for the CFET metal gate structure 508b; an NFET gate region 308c is over a PFET gate region 208c for the CFET metal gate structure 508c; and an NFET gate region 308d is over a PFET gate region 208d for the CFET metal gate structure 508d. The NFET gate regions 308 include gate dielectric layers 304 doped in various concentrations by a suitable dipole dopant (also referred to as n-type dipoles) such as lanthanum for reducing the threshold voltage of the NFET. The PFET gate regions 208 include gate dielectric layers 204 doped in various concentrations by a suitable dipole dopant (also referred to as p-type dipoles) such as zinc for reducing the threshold voltage of the PFET. The gate dielectric layers 304 surround channels 302 for an NFET, and the gate dielectric layers 204 surround channels 202 for a PFET. Each of the respective gate dielectric layers 204 and 304 are surrounded by the metal gate electrode 120.

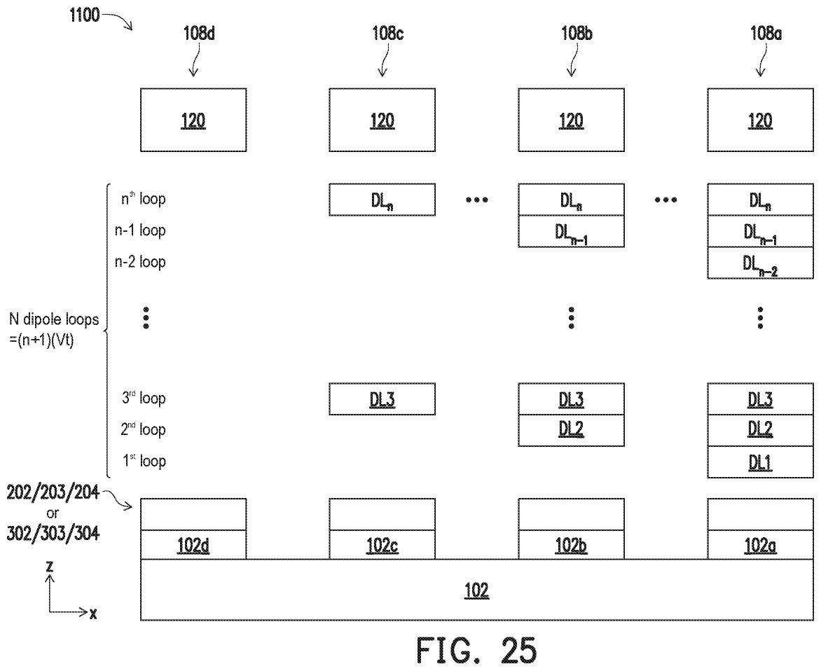

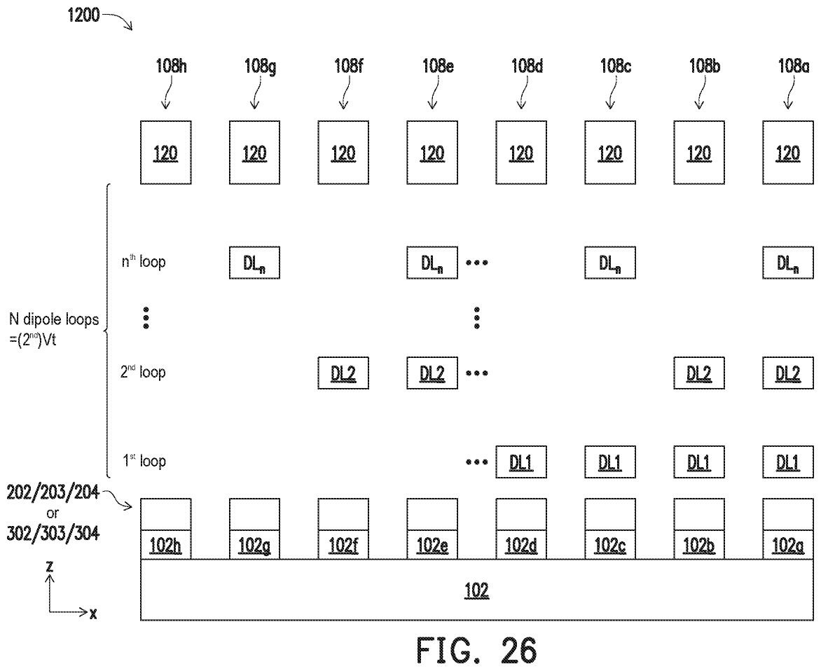

Still referring to FIG. 1, the different dopant concentrations in the gate dielectric layers 304 for NFET gate regions 308a, 308b, 308c, and 308d are illustratively shown by different density of a first pattern fill. For example, in the NFET gate region 308a, n-type dipoles are driven into the gate dielectric layers 304 by performing a dipole loop process 3 times; in the NFET gate region 308b, n-type dipoles are driven into the gate dielectric layers 304 by performing a dipole loop process 2 times; in the NFET gate region 308c, n-type dipoles are driven into the gate dielectric layers 304 by performing a dipole loop process 1 time; and in the NFET gate region 308d, a dipole loop process is not performed and n-type dipoles are not driven into the gate dielectric layers 304. Each dipole loop process involves annealing to selectively drive n-type dipole dopants into the gate dielectric layers 304 in one or more NFET gate regions to the exclusion of another one or more NFET gate regions. This is done through a dipole patterning process that masks certain CFET gate regions 108 before performing each dipole loop, as will explained in more detail with respect to FIGS. 25-26.

Still referring to FIG. 1, the different dopant concentrations in the gate dielectric layers 204 for PFET gate regions 208a, 208b, 208c, and 208d are illustratively shown by different density of a second pattern fill. For example, in the PFET gate region 208a, p-type dipoles are driven into the gate dielectric layers 204 by performing a dipole loop process 3 times; in the PFET gate region 208b, p-type dipoles are driven into the gate dielectric layers 204 by performing a dipole loop process 2 times; in the PFET gate region 208c, p-type dipoles are driven into the gate dielectric layers 204 by performing a dipole loop process 1 time; and in the PFET gate region 208d, a dipole loop process is not performed and p-type dipoles are not driven into the gate dielectric layers 204. Each dipole loop process involves annealing to selectively drive p-type dipole dopants into the gate dielectric layers 204 in one or more PFET gate regions to the exclusion of another one or more PFET gate regions. This is done through a dipole patterning process that masks certain CFET gate regions 108 before performing each dipole loop, as will explained in more detail with respect to FIGS. 25-26.

Still referring to FIG. 1, the monolithic CFET semiconductor device 100 includes CFET metal gate structures 508a, 508b, 508c, and 508d in the CFET gate regions 108a, 108b, 108c, and 108d. In each respective metal gate structure 508a-508d, a metal gate electrode 120 is filled in between semiconductor channels 202/302 in both the PFET and NFET gate regions 208 and 308. Due to the dipole loop processes, the gate dielectric layer is characteristically changed but the dimensions remain. Accordingly, the dimensions of the metal gate electrode 120 across CFET metal gate structures 508a-508d remain the same. That is, gate dimensions are not changed to vary Vt across different CFET devices. For example, a thickness of a portion of the metal gate electrode 120 wrapping around a semiconductor channel 202/302 for a high Vt CFET is substantially the same as a thickness of a portion of the metal gate electrode 120 wrapping around a semiconductor channel 202/302 for a low Vt CFET. As shown in FIG. 1, the thickness of the wrapping portions of metal gate electrode 120 across the CFET metal gate structures 508a-508d are the same. Further, a same metal fill material for the metal gate electrode 120 may be used for both the PFET and NFET gate regions 208 and 308. This is because no p-type and/or n-type specific metal is needed since the respective gate dielectric layers 204/304 are already doped with specific p-type and/or n-type dipoles through the dipole loop processes.

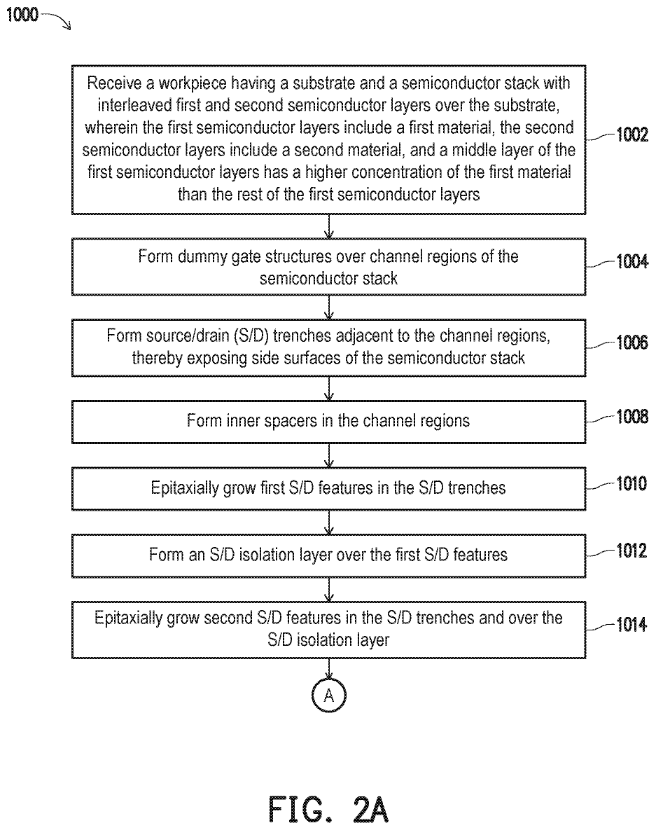

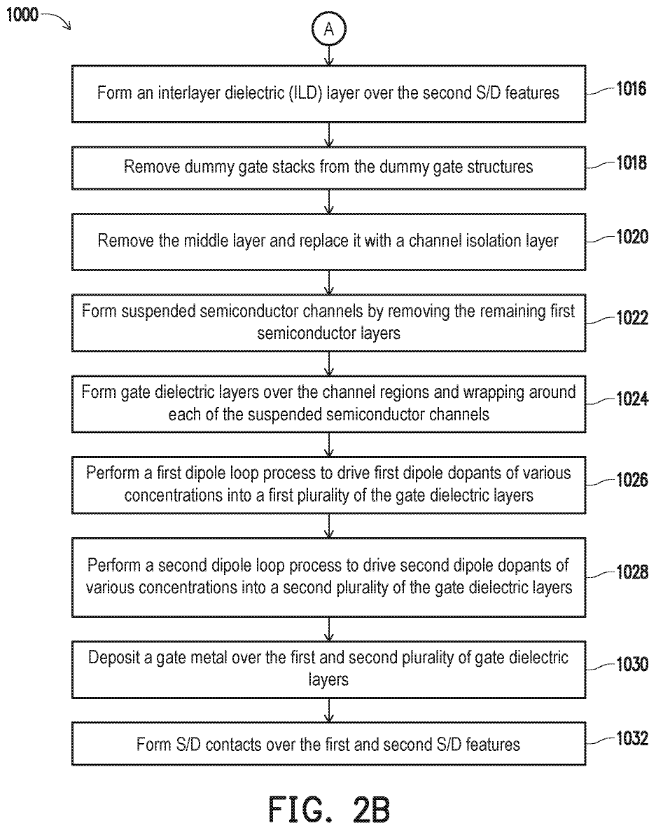

Although FIG. 1 shows an increasing gradient of dipole dopant concentration in the gate dielectric layers 204/304 from left to right (i.e., from the CFET metal gate structures 508d to the CFET metal gate structures 508a), the present disclosure is not limited thereto. Depending on the dipole patterning process, different combinations of dipole dopant concentrations are possible from one CFET gate structure to another. Further, although FIG. 1 is described such that within a same CFET metal gate structure (e.g., 508a), the respective PFET and NFET gate regions (e.g., 208a and 308a) have a same number of dipole loops performed (e.g., both 3 times), the present disclosure is not limited thereto. Depending on the dipole loop process, different combinations of dipole dopant concentrations between PFET and CFET gate regions of a same CFET is also possible. Even further, although FIG. 1 shows NFET gate regions 308 over PFET gate regions 208 for a CFET device where the top device is an NFET and the bottom device is a PFET, the present disclosure is not limited thereto. Aspects of the present disclosure may equally apply to CFET devices where the top device is a PFET and the bottom device is a NFET where PFET gate regions 208 are over the NFET gate regions 308. Additional features not described with respect to FIG. 1 will be made apparent by FIGS. 2A-2B and 3-13 when describing the formation of a monolithic CFET semiconductor device 100.

FIGS. 2A-2B is a flowchart of a method 1000 to form a monolithic CFET semiconductor device 100 having multi Vt offerings, in portion or in entirety, according to various aspects of the present disclosure. The method 1000 is briefly described below. At operation 1002, the method 1000 receives or is provided with a workpiece having a substrate and a semiconductor stack with interleaved first and second semiconductor layers over the substrate. The first semiconductor layers include a first material, the second semiconductor layers include a second material, and a middle layer of the first semiconductor layers has a higher concentration of the first material than the rest of the first semiconductor layers. The first and second semiconductor layers are patterned to form one or more semiconductor stack as active regions, such as fin active regions. At operation 1004, the method 1000 forms dummy gate structures over channel regions of the semiconductor stack. The dummy gate structures include gate spacers and dummy gate stacks. At operation 1006, the method 1000 forms source/drain (S/D) trenches adjacent to the channel regions, thereby exposing side surfaces of the semiconductor stack. At operation 1008, the method 1000 form inner spacers in the channel regions. At operation 1010, the method 1000 epitaxially grows first S/D features in the S/D trenches. At operation 1012, the method 1000 forms an S/D isolation layer over the first S/D features. At operation 1014, the method 1000 epitaxially grows second S/D features in the S/D trenches and over the S/D isolation layer. At operation 1016, the method 1000 forms an interlayer dielectric (ILD) layer over the second S/D features. At operation 1018, the method 1000 removes dummy gate stacks from the dummy gate structures. At operation 1020, the method 1000 removes the middle layer and replaces it with a channel isolation layer. At operation 1022, the method 1000 forms suspended semiconductor channels by removing the remaining first semiconductor layers. At operation 1024, the method 1000 forms gate dielectric layers over the channel regions and wrapping around each of the suspended semiconductor channels.

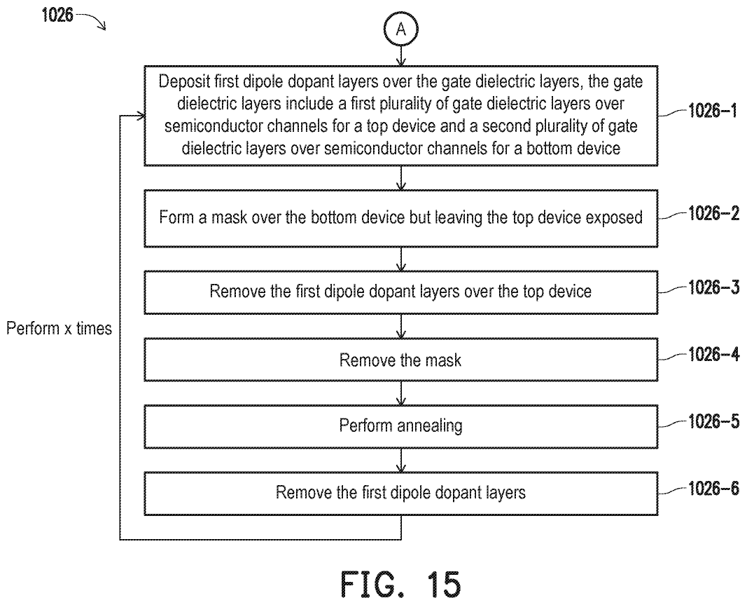

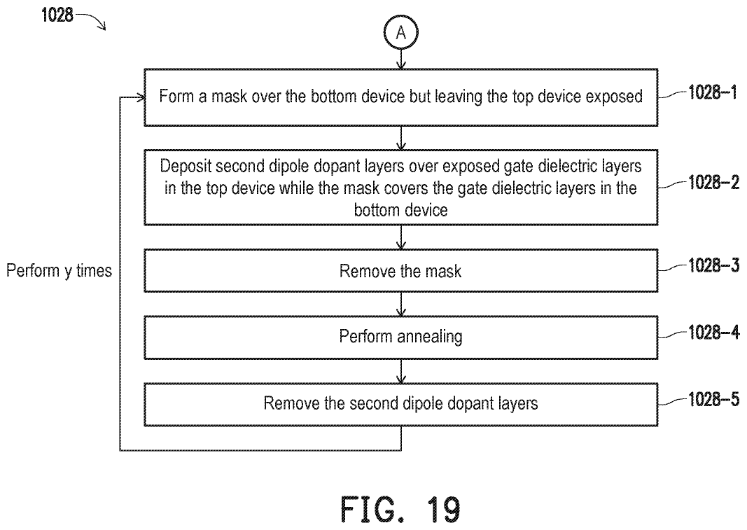

At operation 1026, the method 1000 performs a first dipole loop process to drive first dipole dopants of various concentrations into a first plurality of the gate dielectric layers. This operation is further described in FIG. 15. At operation 1028, the method 1000 performs a second dipole loop process to drive second dipole dopants of various concentrations into a second plurality of the gate dielectric layers. This operation is further described in FIG. 19. At operation 1030, the method 1000 deposits a gate metal over the first and second plurality of gate dielectric layers. The gate metal may be referred to as a metal gate electrode, and after forming the metal gate electrode, metal gate structures are formed. At operation 1032, the method 1000 forms S/D contacts over the first and second S/D features. The method 1000 may perform further steps to complete fabrication of the monolithic CFET device 100. Additional processing is contemplated by the present disclosure. Additional operations can be provided before, during, and after method 1000, and some of the operations described can be moved, replaced, or eliminated for additional embodiments of method 1000.

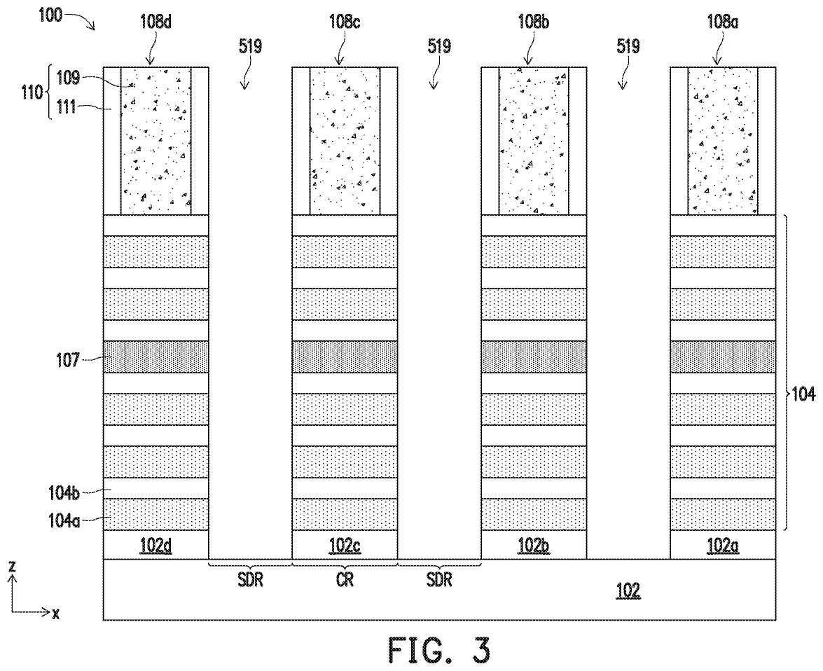

FIGS. 3-13 illustrate cross-sectional views of a monolithic CFET semiconductor device 100 having multi Vt offerings at intermediate stages of fabrication and processed in accordance with the method 1000 of FIGS. 2A-2B. The device 100 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

As shown in FIG. 3 and referring to operation 1002, the method 1000 receives or is provided with a workpiece having a substrate 102 and a semiconductor stack 104 with interleaved first and second semiconductor layers 104a and 104b over the substrate 102. The substrate 102 may be a silicon (Si) substrate, or a substrate having other semiconductor materials such as germanium (Ge), silicon carbide (SiC), silicon germanium (SiGe), or diamond. The semiconductor stack 104 may also be referred to as active regions that extend lengthwise along the x direction. Additional semiconductor stacks 104 may be formed in parallel along the y direction, and the semiconductor stacks 104 are separated from each other by an isolation structure such as a shallow trench isolation (STI) structure (not shown).

The first semiconductor layers 104a have a different material composition than the second semiconductor layers 104b to achieve etch selectivity. For example, each of the first semiconductor layers 104a is made of silicon germanium and each of the second semiconductor layers 104b is made of silicon. Note that the first semiconductor layers 104a include a middle layer 107 that has a different concentration makeup than the rest of the first semiconductor layers 104a. For example, the middle layer 107 is made of silicon germanium but has a greater concentration of germanium than the rest of the first semiconductor layers 104a. In furtherance of the example, the first semiconductor layers 104a are SiGe layers with germanium concentration ranging between 20% and 25% (atomic percentage), and the middle layer 107 is a silicon germanium layer with germanium concentration greater than 30% (atomic percentage), such as ranging between 40% and 60%. This allows for selective etching of the middle layer 107 in a later process step, where the middle layer 107 is replaced with a channel isolation layer to separate a top device from a bottom device of the CFET device 100. Note that the middle layer 107 does not necessarily have to be in the exact middle to separate a top device from a bottom device. This layer may be closer to the top of the stack or closer to the bottom of the stack, and as such, it is possible that the bottom device will have more or less semiconductor channels than the top device. In an embodiment shown in FIG. 3, the first semiconductor layers 104a include a first material (i.e., germanium), the second semiconductor layers 104b include a second material (i.e., silicon), and a middle layer 107 of the first semiconductor layers 104a has a higher concentration of the first material (i.e., germanium) than the rest of the first semiconductor layers 104a. The second semiconductor layers 104b may be of a same material composition as the substrate 102.

Still referring to FIG. 3, the method 1000 at operation 1004 forms dummy gate structures 110 over channel regions CR of the semiconductor stack 104. The channel regions CR include channel regions 102a-102d that are part of the substrate 102. Each of the dummy gate structures 110 includes a dummy gate stack 109 and gate spacers 111 over sidewalls of the dummy gate stack 109. The dummy gate stack 109 may be made of polysilicon and the gate spacers 111 may be made of silicon oxide, silicon nitride, silicon oxycarbide, silicon oxycarbonitride, silicon carbonitride, metal nitride, or a suitable dielectric material.

Still referring to FIG. 3, the method 1000 at operation 1006 forms source/drain (S/D) trenches 519 in S/D regions SDR adjacent to the channel regions CR, thereby exposing side surfaces of the semiconductor stack 104. The S/D trenches 519 may be formed by a dry etching process, a wet etching process, other suitable etching process, or combinations thereof. In some embodiments, the etching process is a multi-step etch process. For example, the etching process may include alternative etchants to separately and alternately remove first semiconductor layers 104a and semiconductor layers 104b. In some embodiments, parameters of the etching process are configured to selectively etch the semiconductor stack 104 with minimal (to no) etching of dummy gate structures 110 (i.e., dummy gate stacks 109 and gate spacers 111). In some embodiments, a lithography process is performed to form a patterned mask layer that covers dummy gate structures 110 and/or portions of an isolation structure between semiconductor stacks 104, and the etching process uses the patterned mask layer as an etch mask when forming the S/D trenches 519. Note that the etching process may also etch slightly into the substrate 102. That is, when forming the S/D trenches 519, the substrate 102 may be recessed to form protruding portions that define the channel regions 102a, 102b, 102c, and 102d.

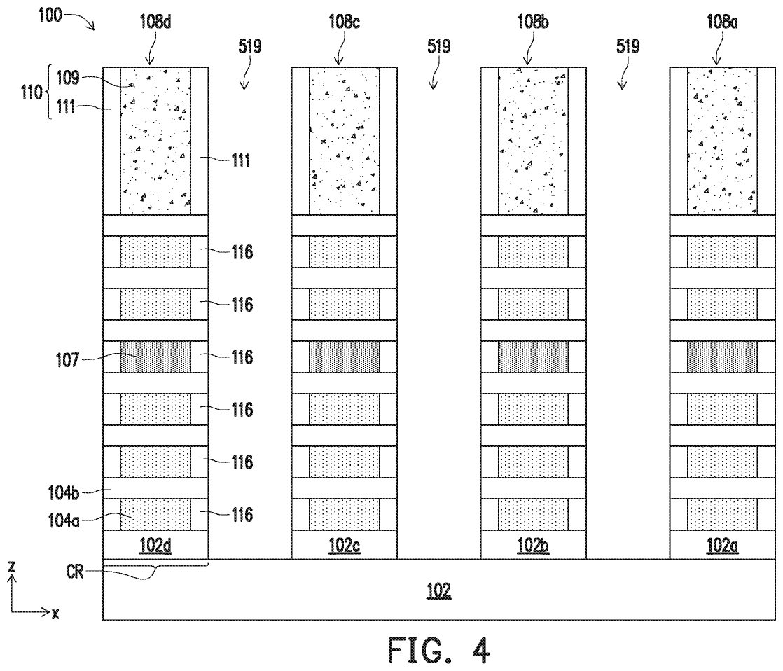

Now referring to FIG. 4, the method 1000 at operation 1008 forms inner spacers 116 in the channel regions CR along sidewalls of the first semiconductor layers 104a by any suitable process. For example, a side etch process is first performed to selectively etch sidewalls of the first semiconductor layers 104a without etching (or substantially etching) the second semiconductor layers 104b. In other words, the side etch process is configured to laterally etch (e.g., along the x direction) first semiconductor layers 104a, thereby reducing a length of first semiconductor layers 104a along the x direction. The side etch process is a dry etching process, a wet etching process, other suitable etching process, or combinations thereof. After the side etch process is performed, air gaps are formed under each of the second semiconductor layers 104b. Then, as shown in FIG. 4, inner spacers 116 are formed in each of the air gaps. The inner spacers 116 are disposed directly below the gate spacers 111, and they may be substantially vertically aligned with the gate spacers 111 along the z direction.

The inner spacers 116 may be formed by a spacer deposition process and a spacer etching process. For example, a spacer deposition process is performed to form a spacer layer over the dummy gate structures 110 and over features defining the S/D trenches 519 (e.g., semiconductor layers 104a, semiconductor layers 104b, and substrate 102). The spacer deposition process may include processes such as CVD, PVD, ALD, HDPCVD, MOCVD, RPCVD, PECVD, LPCVD, ALCVD, APCVD, plating, other suitable methods, or combinations thereof. The spacer layer partially (and, in some embodiments, completely) fills the S/D trenches 519. The spacer deposition process is configured to ensure that the spacer layer fills the air gaps between semiconductor layers 104b and between semiconductor layers 104b and the respective channel regions 102a-102d under gate spacers 111. A spacer etching process is then performed that selectively etches the spacer layer to form inner spacers 116 as depicted in FIG. 4 with minimal (to no) etching of semiconductor layers 104b, dummy gate stacks 109, and gate spacers 111. In the disclosed embodiment, the spacer etching process includes an anisotropic etching, such as plasma etch. The spacer layer (and thus inner spacers 116) includes a material that is different than a material of semiconductor layers 104b and a material of gate spacers 111 to achieve desired etching selectivity during the gate spacer etching process. In some embodiments, the spacer layer includes a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the spacer layer includes a low-k dielectric material.

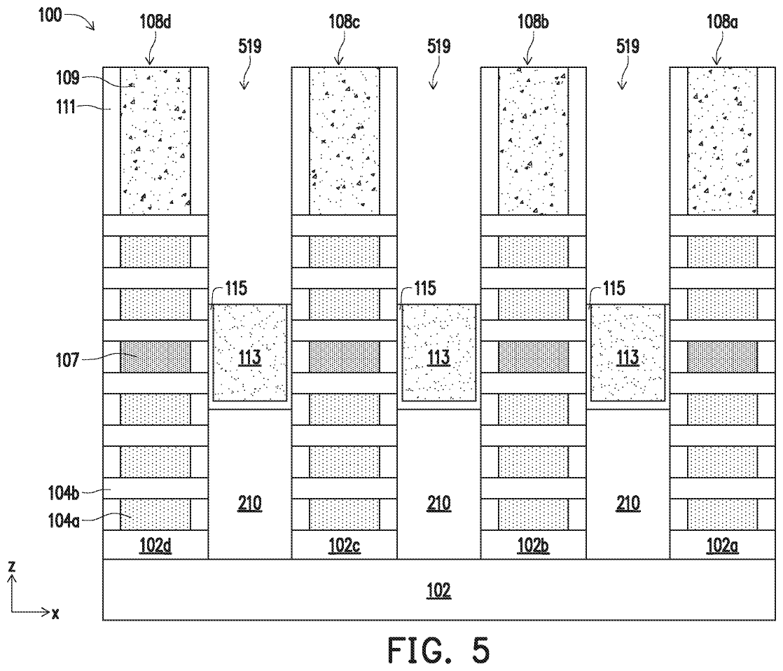

Now referring to FIG. 5, the method 1000 at operation 1010 epitaxially grows first S/D features 210 in the S/D trenches 519 for bottom transistor devices of the CFET device 100. The bottom transistor devices may be NFET transistor devices or PFET transistor devices. As such, the first source/drain features 210 may include n-type source/drain features that correspond with n-type transistor regions or p-type source/drain features that correspond with p-type transistor regions. The first source/drain features 210 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of substrate 102 and/or semiconductor stacks 104 (in particular, semiconductor layers 104b). Epitaxial source/drain features are doped with n-type dopants and/or p-type dopants. In some embodiments, for the n-type CFET transistors, first epitaxial source/drain features 210 include silicon and can be doped with phosphorous, arsenic, other n-type dopant, or combinations thereof (for example, forming Si:C epitaxial source/drain features, Si:P epitaxial source/drain features, or silicon carbon doped with phosphorus—SiC:P epitaxial source/drain features). In some embodiments, for the p-type CFET transistors, first epitaxial source/drain features 210 include silicon germanium or germanium and can be doped with boron, other p-type dopant, or combinations thereof (for example, forming Si:Ge:B epitaxial source/drain features). In the embodiment shown, the first S/D features 210 are p-type S/D features for PFET devices.

Still referring to FIG. 5, the first S/D features 210 only partially fill the S/D trenches 519. Specifically, they are grown (or grown and recessed) to a height below the middle layer 107 in the z direction. That is, the first S/D features 210 are in direct contact with semiconductor layers 104b for bottom transistor devices under the middle layer 107, but not the semiconductor layers 104b above the middle layer 107. Note that in some embodiments, like as shown, the first S/D features 210 need not be in direct contact with all the semiconductor layers 104b under the middle layer 107.

Still referring to FIG. 5, the method 1000 at operation 1012 forms an S/D isolation layer 113 over the first S/D features 210. This may be done by first conformably depositing a dielectric liner such as an etch stop layer 115 by CVD, ALD or other suitable processes, then depositing the S/D isolation layer 113 over the etch stop layer 115. An etch process may follow to recess top surfaces of the isolation layer 113 and etch stop layer 115. In some embodiments, the operation 1012 includes depositing the etch stop layer 115 and the isolation layer 113, performing a chemical mechanical polishing (CMP), and etching to recess the deposited materials. In some embodiments, the operation 1012 may apply a selective deposition. The etch stop layer 115 may include silicon nitride and the S/D isolation layer 113 may include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the S/D isolation layer 113 includes a low-k dielectric material.

The S/D isolation layer 113 only partially fill the S/D trenches 519 since second S/D features 310 are to be formed over the S/D isolation layer 113. However, although only partially filled, the S/D isolation layer 113 should be thick enough to isolate the first S/D features 210 from the later formed second S/D features 310. As such, in some embodiments, like as shown, the S/D isolation layer 113 (or etch stop layer 115) may be in direct contact with sidewalls of the second semiconductor layers 104b, thereby isolating them from contacting the first or second S/D features 210 and 310. The S/D isolation layer 113 has a portion horizontally aligned with the middle layer 107 along the x direction. The S/D isolation layer 113 is separated from the middle layer 107 by inner spacers 116. In an embodiment, the S/D isolation layer 113 has a thickness in the z direction greater than a thickness of the middle layer 107.

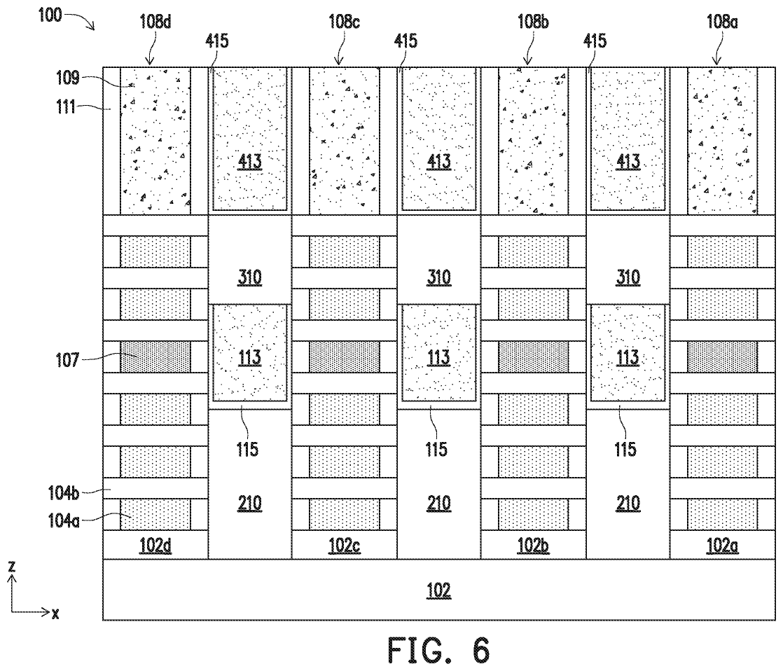

Now referring to FIG. 6, the method 1000 at operation 1014 epitaxially grows second S/D features 310 in the S/D trenches 519 and over the S/D isolation layer 113 for top transistor devices of the CFET device 100. The top transistor devices may be NFET transistor devices or PFET transistor devices. As such, the second source/drain features 310 may include n-type source/drain features that correspond with n-type transistor regions or p-type source/drain features that correspond with p-type transistor regions. The second source/drain features 310 may be formed by an epitaxy process using CVD deposition techniques (for example, VPE and/or UHV-CVD), molecular beam epitaxy, other suitable epitaxial growth processes, or combinations thereof. The epitaxy process can use gaseous and/or liquid precursors, which interact with the composition of semiconductor stacks 104 (in particular, semiconductor layers 104b). Epitaxial source/drain features are doped with n-type dopants and/or p-type dopants. In some embodiments, for the n-type CFET transistors, second epitaxial source/drain features 310 include silicon and can be doped with phosphorous, arsenic, other n-type dopant, or combinations thereof (for example, forming Si:C epitaxial source/drain features, Si:P epitaxial source/drain features, or silicon carbon doped with phosphorus—SiC:P epitaxial source/drain features). In some embodiments, for the p-type CFET transistors, second epitaxial source/drain features 310 include silicon germanium or germanium and can be doped with boron, other p-type dopant, or combinations thereof (for example, forming Si:Ge:B epitaxial source/drain features). In the embodiment shown, the second S/D features 310 are n-type S/D features for NFET devices.

Still referring to FIG. 6, the second S/D features 310 may completely fill the S/D trenches 519 such that top surfaces of the second S/D features 310 are substantially coplanar with top surfaces of the topmost second semiconductor layers 104b. Alternatively, the second S/D features 310 may grow above the top surfaces of the topmost second semiconductor layers 104b. Note that the second S/D features 310 are in direct contact with semiconductor layers 104b for top transistor devices above the middle layer 107, but not the semiconductor layers 104b below the middle layer 107. Note that in some embodiments, like as shown, the second S/D features 310 need not be in direct contact with all the semiconductor layers 104b above the middle layer 107.

Still referring to FIG. 6, the method 1000 at operation 1016 forms an interlayer dielectric (ILD) layer 413 over the second S/D features 310. This may be done by first conformably depositing a dielectric liner such as an etch stop layer 415 by CVD, ALD or other suitable processes, then depositing the ILD layer 413 over the etch stop layer 415. A planarization process such as CMP may follow to planarize top surfaces of the ILD layer 413, etch stop layer 415, and dummy gate structures 110. The etch stop layer 415 may include silicon nitride and the ILD layer 413 may include a dielectric material that includes for example, silicon oxide, silicon nitride, silicon oxynitride, tetraethoxysilane (TEOS) formed oxide, Phosphosilicate Glass (PSG), Boron-Doped Phosphosilicate Glass (BPSG), low-k dielectric material, other suitable dielectric material, or combinations thereof.

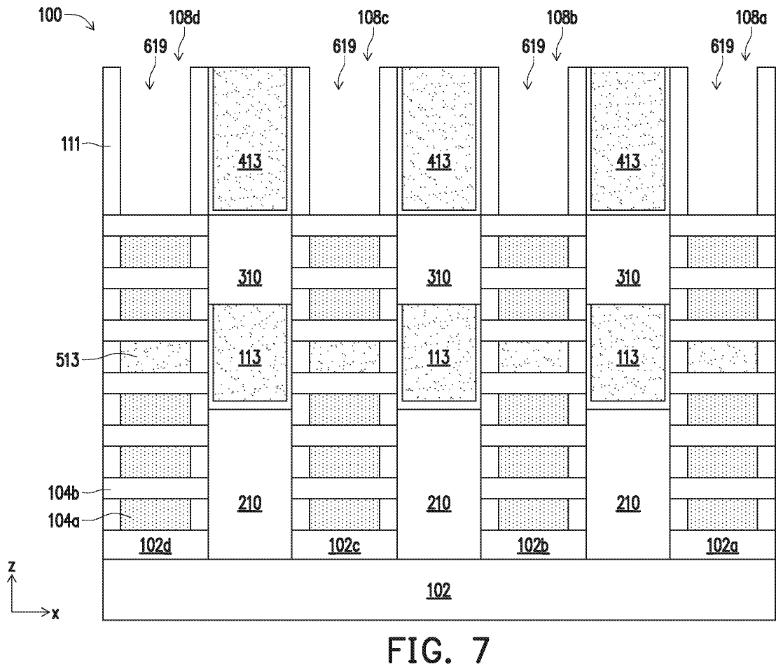

Now referring to FIG. 7, the method 1000 at operation 1018 removes dummy gate stacks 109 from the dummy gate structures 110. The dummy gate stacks 110 are removed by a suitable etching process, thereby resulting in gate trenches 619 and exposing the semiconductor stacks 104. The etching process is designed with an etchant to selectively remove the dummy gate stacks 109. In the depicted embodiment, an etching process completely removes dummy gate stacks 109 to expose surfaces of the semiconductor layers 104a and semiconductor layers 104b in the x-z plane. The etching process is a dry etching process, a wet etching process, other suitable etching process, or combinations thereof. In some embodiments, the etching process is a multi-step etch process. For example, the etching process may include alternative etchants to separately remove various layers of dummy gate stacks 109, such as the dummy gate electrode layers, the dummy gate dielectric layers, and/or the hard mask layers. In some embodiments, the etching process is configured to selectively etch dummy gate stacks 109 with minimal (to no) etching of other features of the device 100, such as ILD layer 413, gate spacers 111, semiconductor layers 104a, and semiconductor layers 104b. In some embodiments, a lithography process is performed to form a patterned mask layer that covers the ILD layer 413 and/or gate spacers 111, and the etching process uses the patterned mask layer as an etch mask.

Still referring to FIG. 7, the method 1000 at operation 1020 removes the middle layer 107 and replaces it with a channel isolation layer 513. The middle layer 107 is removed by a suitable etching process. The etching process is designed with an etchant to selectively remove the middle layer 107. As described above, the middle layer 107 has a different concentration of materials such as heavier germanium concentration than other first semiconductor layers 104a (which also include germanium). This allows for selective etching of the middle layer 107 without etching the remaining semiconductor layers 104a. Thereafter, the air void that remains is filled with a dielectric material to form the channel isolation layer 513. The channel isolation layer 513 may include a dielectric material that includes silicon, oxygen, carbon, nitrogen, other suitable material, or combinations thereof (for example, silicon oxide, silicon nitride, silicon oxynitride, silicon carbide, or silicon oxycarbonitride). In some embodiments, the S/D isolation layer 113 includes a low-k dielectric material. In some embodiments, the formation of the channel isolation layer 513 includes etching, deposition, and anisotropic etch, such as plasma etch.

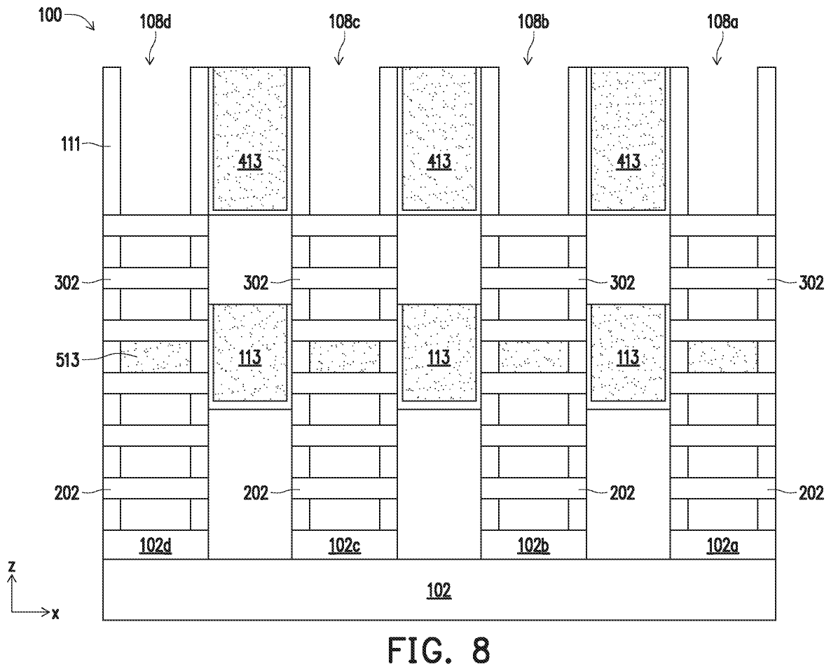

Now referring to FIG. 8, the method 1000 at operation 1022 forms suspended semiconductor channels 202/302 by removing the remaining first semiconductor layers 104a by a suitable etching process. The etching process is designed with an etchant to selectively remove the remaining first semiconductor layers 104a without substantially etching the second semiconductor layers 104b and the channel isolation layer 513. As such, the second semiconductor layers 104b become suspended semiconductor channels 202/302. The suspended semiconductor channels 202 refer to channel layers for the bottom transistor devices (e.g., PFET channels of the CFET device 100) and the suspended semiconductor channels 302 refer to channel layers for the top transistor devices (e.g., NFET channels of the CFET device 100).

With respect to selectively etching the middle layer 107 and selectively etching the first semiconductor layers 104a, various etching parameters can be tuned such as etchant composition, etching temperature, etching solution concentration, etching time, etching pressure, source power, RF bias voltage, RF bias power, etchant flow rate, other suitable etching parameters, or combinations thereof. For example, an etchant is selected to etch the material of the middle layer 107 (e.g., highest concentration of germanium) at a higher rate than the remaining semiconductor layers 104a (e.g., middle concentration of germanium). And an etchant is selected for the etching process that etches the semiconductor layers 104a (e.g., middle concentration of germanium) at a higher rate than the material of the semiconductor layers 104b (e.g., lowest concentration of germanium or no germanium). The etching process is a dry etching process, a wet etching process, other suitable etching process, or combinations thereof. In some embodiments, a dry etching process (such as an RIE process) utilizes a fluorine-containing gas (for example, SF6) to selectively etch the semiconductor layers. In some embodiments, a ratio of the fluorine-containing gas to an oxygen-containing gas (for example, O2), an etching temperature, and/or an RF power may be tuned to selectively etch silicon germanium (or silicon). In some embodiments, a wet etching process is performed with an etching solution that includes ammonium hydroxide (NH4OH) and water (H2O) to selectively etch the germanium-containing semiconductor layers. In some embodiments, a chemical vapor phase etching process using hydrochloric acid (HCl) is used.

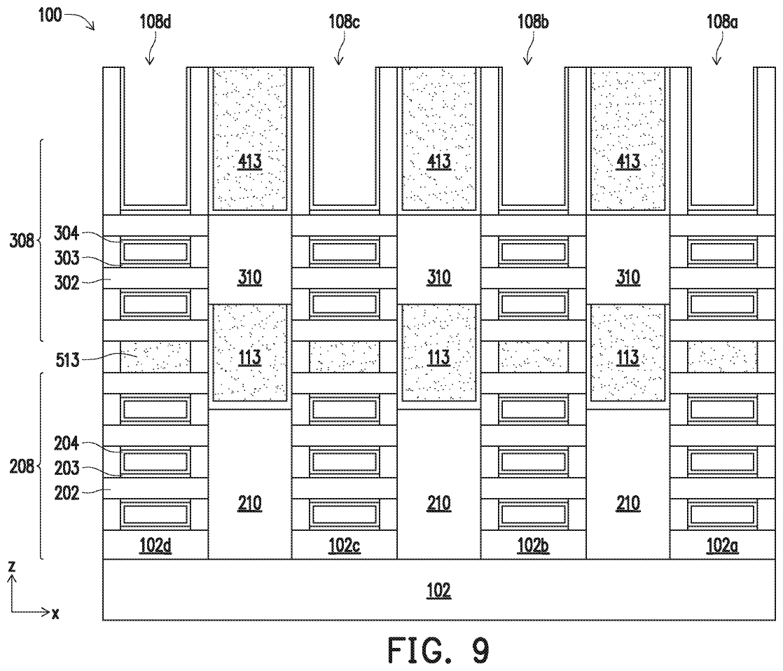

Now referring to FIG. 9, the method 1000 at operation 1024 forms gate dielectric layers 204/304 over the channel regions 102a-102d and wrapping around each of the suspended semiconductor channels 202/302. The gate dielectric layers 204/304 partially fills the gaps between the suspended semiconductor channels 202/302 and may include high-k dielectric materials such as HfO₂, HfSiO, HfSiO₄, HfSiON, HfLaO, HfTaO, HfTiO, HfZrO, HfAlOx, ZrO, ZrO₂, ZrSiO₂, AlO, AlSiO, Al₂O₃, TiO, TiO₂, LaO, LaSiO, Ta₂O₃, Ta₂Os, Y₂O₃, SrTiO₃, BaZrO, BaTiO₃ (BTO), (Ba,Sr)TiO₃ (BST), Si₃N₄, hafnium dioxide-alumina (HfO₂—Al₂O₃) alloy, other suitable high-k dielectric material, or combinations thereof. The gate dielectric layers 204/304 may be formed by any of the processes described herein, such as ALD, CVD, PVD, oxidation-based deposition process, other suitable process, or combinations thereof. In an embodiment, before forming the gate dielectric layers 204/304, interfacial layers 203/303 are formed on the channel layers 202/302. The interfacial layers 203/303 may be formed by thermal oxidation, chemical oxidation, ALD, CVD, or other suitable processes. The interfacial layers 203/303 may include a dielectric material, such as SiO₂, HfSiO, SiON, other silicon-containing dielectric material, other suitable dielectric material, or combinations thereof.

Still referring to FIG. 9, PFET gate regions 208 of the CFET gate regions 108 include interfacial layers 203 directly on top and bottom surfaces of the channel layers 202, and gate dielectric layers 204 directly on top and bottom surfaces of the interfacial layers 203 and on side surfaces of the inner spacers 116. NFET gate regions 308 of the CFET gate regions 108 include interfacial layers 303 directly on top and bottom surfaces of the channel layers 302, and gate dielectric layers 304 directly on top and bottom surfaces of the interfacial layers 303 and on side surfaces of the inner spacers 116 (and/or the gate spacers 111). In the depicted embodiment, the NFET gate regions 308 are vertically above the PFET gate regions such that NFET devices are formed over PFET devices. However, the present disclosure is not limited thereto. In other embodiments, the PFET gate regions 208 may be above the NFET gate regions 308 such that PFET devices are formed over NFET devices.

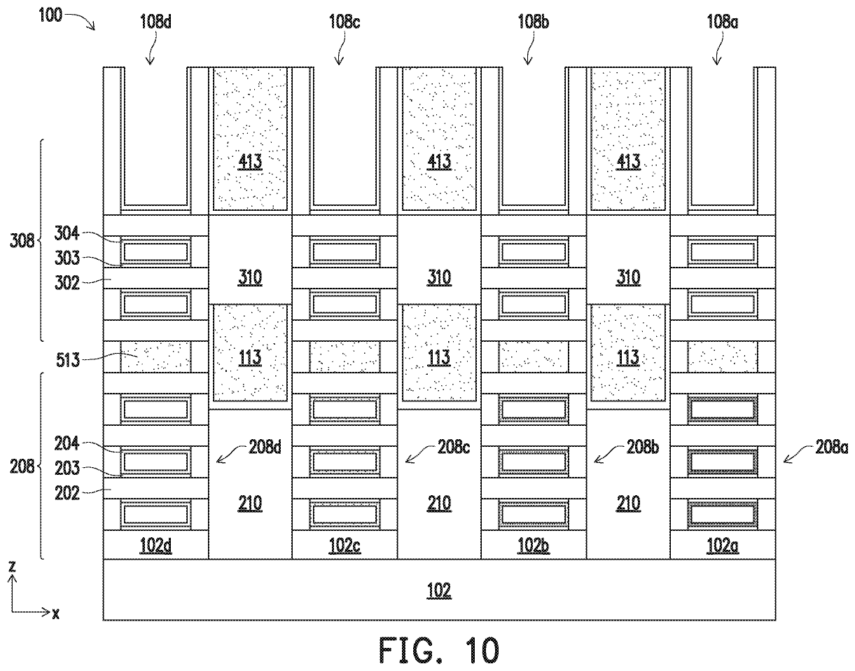

Now referring to FIG. 10, the method 1000 at operation 1026 performs a first dipole loop process to drive first dipole dopants of various concentrations into a first plurality of the gate dielectric layers. This operation performs doping in the bottom transistor regions (e.g., PFET regions of the CFET device). For example, in the depicted embodiment, the first dipole loop process is performed to dope the gate dielectric layers 204 in the PFET gate regions 208 but not dope the gate dielectric layers 304 in the NFET gate regions 308. This operation is further described in more detail with respect to FIG. 15, which involves annealing dipole dopant layers of a first conductivity type (e.g., p-type) to drive first dopants (e.g., zinc) into the gate dielectric layers 204.

Note that within the PFET gate regions 208, the concentration of the first dopants may vary between CFET gate regions 108a-108d. Or more specifically, the concentration of the first dopants may vary between PFET gate regions 208a-208d of the different CFET gate regions 108a-108d, respectively. For example, as illustratively indicated by the fill patterns, the gate dielectric layers 204 in the PFET gate region 208a are more heavily doped than the gate dielectric layers 204 in the PFET gate region 208b, the gate dielectric layers 204 in the PFET gate region 208b are more heavily doped than the gate dielectric layers 204 in the PFET gate region 208c, and the gate dielectric layers 204 in the PFET gate region 208c are more heavily doped than the gate dielectric layers 204 in the PFET gate region 208d. In this case, the gate dielectric layers 204 in the CFET gate region 108a may experience 3 dipole loops of annealing, the gate dielectric layers 204 in the CFET gate region 108b may experience 2 dipole loops of annealing, the gate dielectric layers 204 in the CFET gate region 108c may experience 1 dipole loops of annealing, and the gate dielectric layers 204 in the CFET gate region 108d may experience 0 dipole loops of annealing. This variation in dipole dopant concentration across different CFET gate regions is made possible through a dipole patterning process, which will be described in more detail with respect to FIGS. 25-26. Depending on the dipole patterning process, other variations of dopant concentration across CFET gate regions 108 is possible.

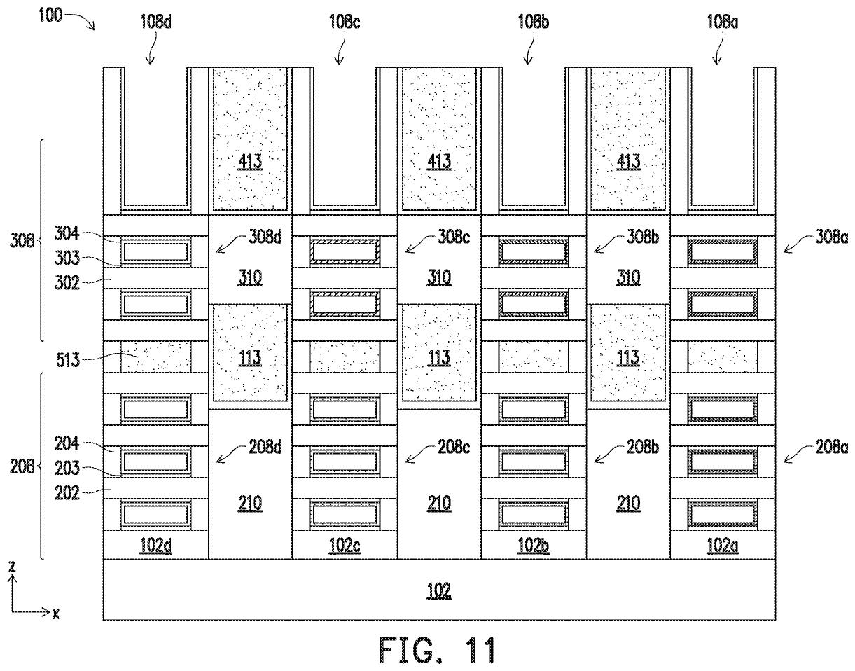

Now referring to FIG. 11, the method 1000 at operation 1028 performs a second dipole loop process to drive second dipole dopants of various concentrations into a second plurality of the gate dielectric layers. This operation performs doping in the top transistor regions (e.g., NFET regions). For example, in the depicted embodiment, the second dipole loop process is performed to dope the gate dielectric layers 304 in the NFET gate regions 308 but not dope the gate dielectric layers 204 in the PFET gate regions 208. This operation is further described in more detail with respect to FIG. 19, which involves annealing dipole dopant layers of a second conductivity type (e.g., n-type) to drive second dopants (e.g., lanthanum) into the gate dielectric layers 304.

Note that within the NFET gate regions 308, the concentration of the second dopants may vary between CFET gate regions 108a-108d. Or more specifically, the concentration of the second dopants may vary between NFET gate regions 308a-308d of the different CFET gate regions 108a-108d, respectively. For example, as illustratively indicated by the fill patterns, the gate dielectric layers 304 in the NFET gate region 308a are more heavily doped than the gate dielectric layers 304 in the NFET gate region 308b, the gate dielectric layers 304 in the NFET gate region 308b are more heavily doped than the gate dielectric layers 304 in the NFET gate region 308c, and the gate dielectric layers 304 in the NFET gate region 308c are more heavily doped than the gate dielectric layers 304 in the NFET gate region 308d. In this case, the gate dielectric layers 304 in the CFET gate region 108a may experience 3 dipole loops of annealing, the gate dielectric layers 304 in the CFET gate region 108b may experience 2 dipole loops of annealing, the gate dielectric layers 304 in the CFET gate region 108c may experience 1 dipole loops of annealing, and the gate dielectric layers 304 in the CFET gate region 108d may experience 0 dipole loops of annealing. This variation in dipole dopant concentration across different CFET gate regions is made possible through a dipole patterning process, which will be described in more detail with respect to FIGS. 25-26. Depending on the dipole patterning process, other variations of dopant concentration across CFET gate regions 108 is possible.

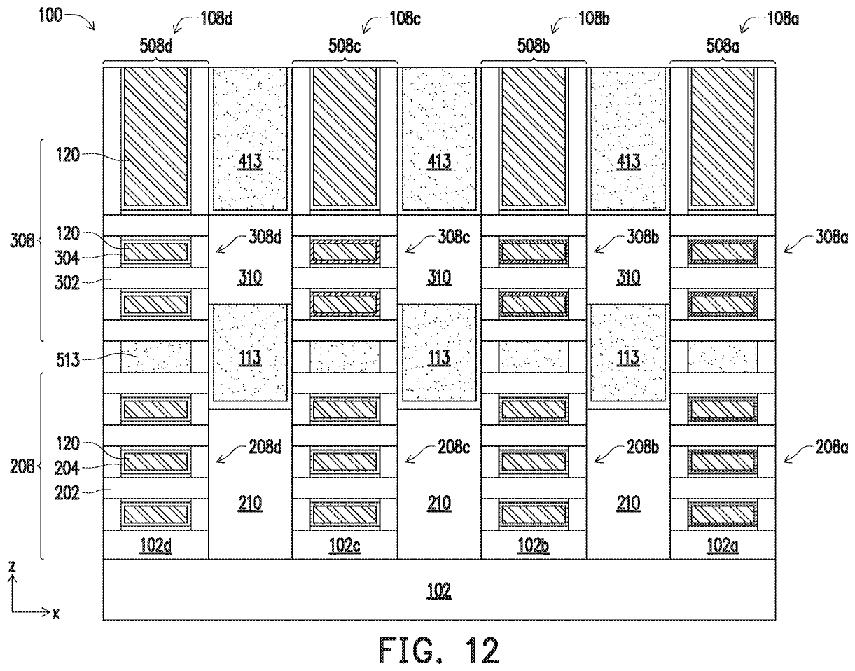

Now referring to FIG. 12, the method 1000 at operation 1030 deposits a gate metal 120 (also referred to as a metal gate electrode) over the first and second plurality of gate dielectric layers 204/304, thereby forming respective CFET metal gate structures 508a, 508b, 508c, and 508d. The gate metal 120 deposited is deposited over both the PFET gate regions 208 and the NFET gate regions 308, and the gate metal 120 in both of the regions are of a same metal material. The same metal material may include tungsten. The gate metal 120 do not need to include additional n-type or p-type work function metals for respective PFET and NFET gate regions 208 and 308. This is because the gate dielectric layers 204/304 are already doped in such a way to account for n-type or p-type specificity. In this way, threshold voltages may be varied while keeping the same consistent dimensions for each CFET metal gate structures 508a-508d.

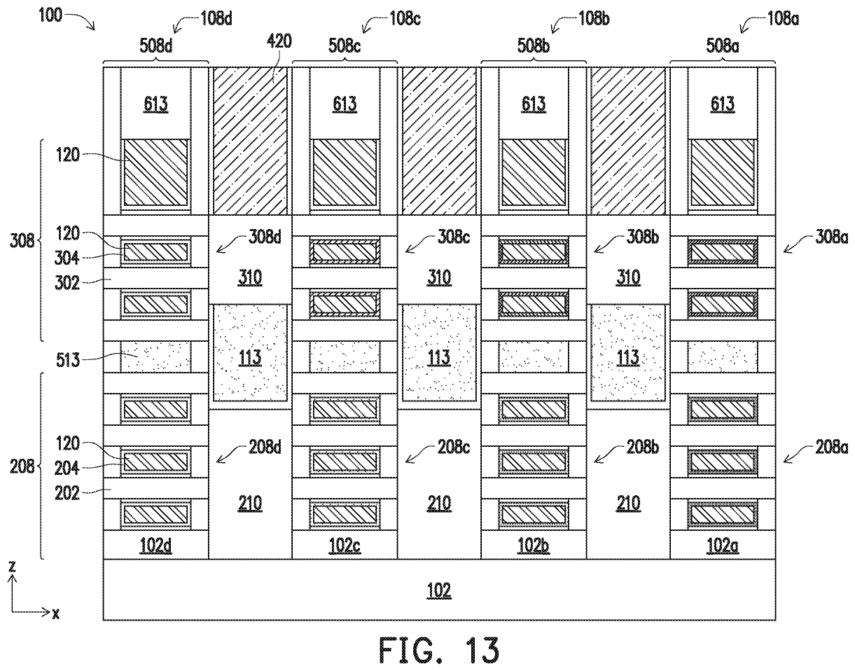

Now referring to FIG. 13, the method 1000 at operation 1032 forms S/D contacts 420 over the first and second S/D features 210 and 310. The S/D contacts 420 may be formed by first forming trenches through the ILD layer 413 and through the etch stop layers 415 by any suitable patterning process that further includes a lithography process and an etching process. The trenches expose top surfaces of the S/D features 310. Then, metal contact features are deposited into the trenches. The metal contact features may include silicide features and a metal fill layer over the silicide features to collectively form the S/D contacts 420. The silicide features may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. The metal fill layer over the silicide features may include titanium (Ti), ruthenium (Ru), copper (Cu), nickel (Ni), cobalt (Co), tungsten (W), tantalum (Ta), or molybdenum (Mo). Forming the S/D contacts 420 may include a CMP process to remove excess metal. In an embodiment, before forming the S/D contacts 420, gate dielectric caps 613 are formed over the CFET gate regions 108. The gate dielectric caps 613 may be formed by recessing top portions of the CFET metal gate structures 508a-508d and filling the recessed portion with a dielectric material such as silicon oxide, silicon nitride, silicon oxynitride, silicon carbide, or silicon oxycarbonitride. A CMP process may be performed thereafter and before forming the S/D contacts 420.

The method 1000 may perform further steps to complete fabrication of the device 100. Additional processing such as forming metal vias and interconnects (not shown) is contemplated by the present disclosure. Additional operations can be provided before, during, and after method 1000, and some of the operations described can be moved, replaced, or eliminated for additional embodiments of method 1000.

In the embodiments shown, the dipole dopants driven into the gate dielectric layers 204/304 may be driven into an interface between the interfacial layers 203/303 and the gate dielectric layers 204/304. Further, although not shown, the first and second dipole loop processes in operations 1026 and 1028 may be performed on the interfacial layers 203/303 before forming the gate dielectric layers 204/304. As such, the respective n-type and p-type dipole dopants are driven into the interfacial layers 203/303 instead of the gate dielectric layers 204/304. Then, the gate dielectric layers 204/304 are formed over the interfacial layers 203/303, followed by depositing the gate metal 120 in operation 1030. This alternative embodiment is another way to vary gate threshold voltages without altering gate dimensions, in accordance with the disclosed aspects of the present disclosure.

Specific steps for performing the first and second dipole loop processes (operation 1026 and 1028) are detailed below. Note that the first dipole loop process is performed to drive dopants into gate dielectric layers in the bottom transistor regions of the CFET device 100. And the second dipole loop process is performed to drive dopants into gate dielectric layers in the top transistor regions of the CFET device 100. The depicted embodiment shows performing the first dipole loop process before performing the second dipole loop process. However, the present disclosure also contemplates performing the second dipole loop process before performing the first dipole loop process. The depicted embodiment shows the bottom transistor regions being PFET transistor regions and top transistor regions being NFET transistor regions. However, the present disclosure also contemplates the bottom transistor regions being NFET transistor regions and top transistor regions being PFET transistor regions.

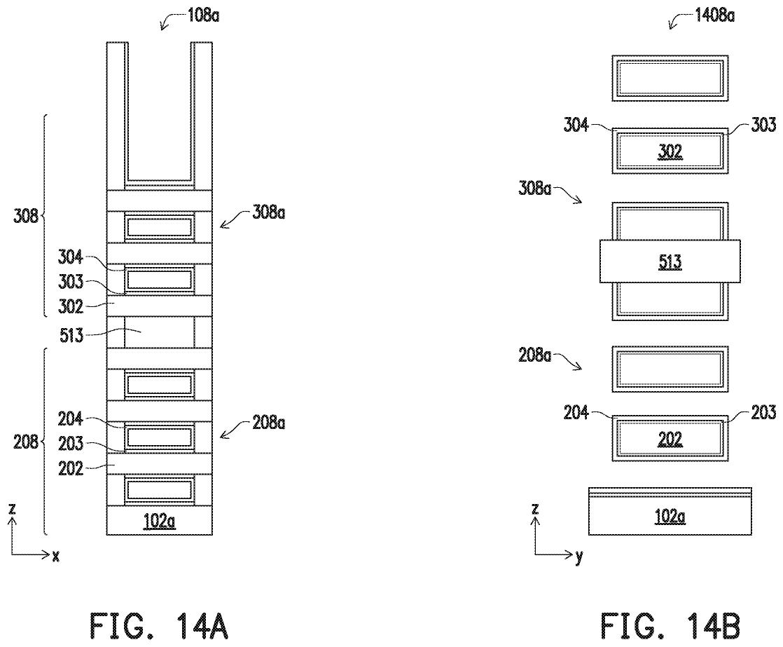

FIG. 14A illustrates an x cross-sectional view of the CFET gate region 108a before performing the first dipole loop process (operation 1026). The CFET gate region 108a corresponds to the CFET gate region 108a in FIG. 9, and the features will not be described again for the sake of brevity.

FIG. 14B illustrates a y cross-sectional view of a CFET channel region 1408a before performing the first dipole loop process (operation 1026). The channel region 1408a shows the same features in FIG. 14A in a perpendicular view. In this view, the cross-sectional cut is along the length of a CFET metal gate structure 508a (not shown here) to be formed over the channel region 102a and the suspended channel layers 202/302. In the bottom gate region (e.g., PFET gate region 208a), the channel layers 202 are wrapped around by the interfacial layers 203 in the y-z plane, and the interfacial layers 203 are wrapped around by the gate dielectric layers 204 in the y-z plane. In the top gate region (e.g., NFET gate region 308a), the channel layers 302 are wrapped around by the interfacial layers 303 in the y-z plane, and the interfacial layers 303 are wrapped around by the gate dielectric layers 304 in the y-z plane. The gate dielectric layers 202/304 do not completely fill the spaces between the suspended channel layers 202/302, and a void remains between the suspended channel layers 202/302.

Still referring to FIG. 14B, the channel isolation layer 513 may completely fill the space between the topmost channel layer 202 and the bottommost channel layer 302. As shown, the channel isolation layer 513 may directly contact the topmost channel layer 202 and the bottommost channel layer 302. Respective interfacial layers 203/303 and gate dielectric layers 204/304 do not wrap around surfaces where the channel isolation layer 513 directly contact the topmost channel layer 202 and the bottommost channel layer 302. As shown, the channel isolation layer 513 may have a greater width in the y direction than a width of the channel layers 202/303 wrapped around by the gate dielectric layers 204/304.

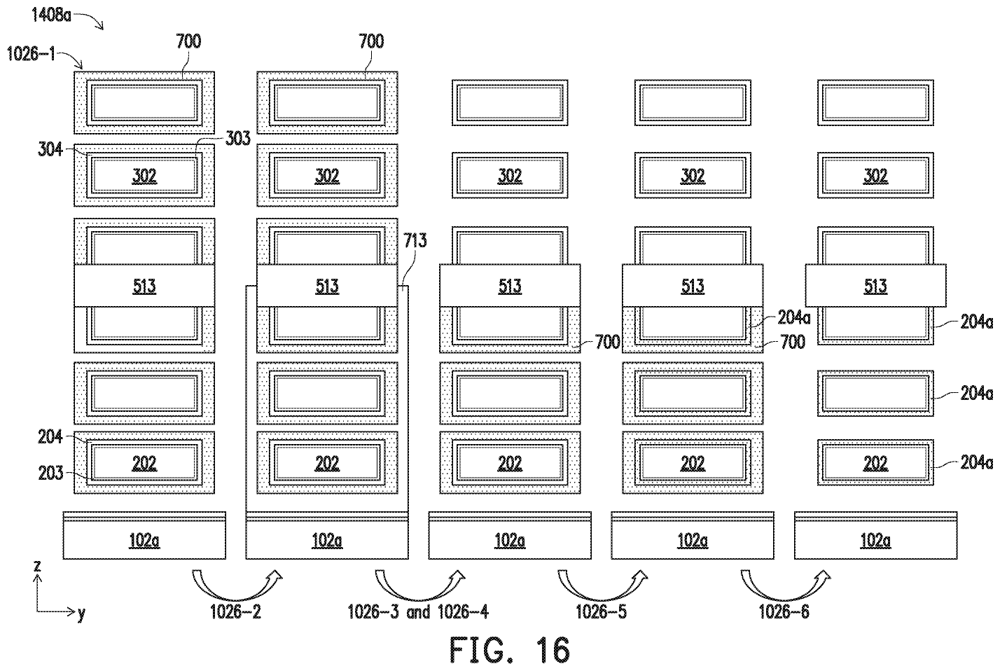

FIG. 15 is a flow chart of a method to perform a first dipole loop process. Specifically, FIG. 15 shows a flow chart of operation 1026 (described above), which is now broken into additional steps. The operation 1026 in FIG. 15 is described below in conjunction with FIG. 16, which illustrates y cross-sectional views of the CFET channel region 1408a at intermediate stages of fabrication and processed in accordance with the method of FIG. 15.

Now referring to FIG. 16, at step 1026-1, the operation 1026 deposits first dipole dopant layers 700 (e.g., p-type dopant layers) over the gate dielectric layers 204 and 304. These gate dielectric layers include a first plurality of gate dielectric layers 304 over semiconductor channels 302 for a top device (e.g., NFET device) and a second plurality of gate dielectric layers 204 over semiconductor channels 202 for a bottom device (e.g., PFET device). The first dipole dopant layers 700 wrap around the respective gate dielectric layers 204 and 304 in the CFET channel region 1408a. The first dipole dopant layer 700 may include p-type dipole dopants such as zinc. For example, the first dipole dopant layer 700 may be a zinc oxide layer. Due to the presence of the channel isolation layer 513, the first dipole dopant layer 700 may not completely wrap around the bottommost channel layer 302 and the topmost channel layer 202 (i.e., top and bottom surfaces of the respective channel layers 202/302 are covered by the channel isolation layer 513).

Still referring to FIG. 16, at step 1026-2, the operation 1026 forms a mask 713 (e.g., hard mask) over the bottom device but leaving the top device exposed. Specifically, the hard mask selectively covers all the first dipole dopant layers 700 surrounding channel layers 202, which are below the channel isolation layer 513. At step 1026-3, the operation 1026 removes the exposed first dipole dopant layers 700 that surrounds channel layers 302, which are above the channel isolation layer 513. At step 1026-4, the operation 1026 removes the mask 713 by a suitable process. At step 1026-5, the operation 1026 performs annealing to drive dipole dopants (metal atoms) from the first dipole dopant layer 700 into the gate dielectric layers 204 and/or interfacial layers 203, thereby forming doped gate dielectric layers 204a. At step 1026-6, the operation 1026 removes the first dipole dopant layers 700 from the CFET channel region 1408a by etching.

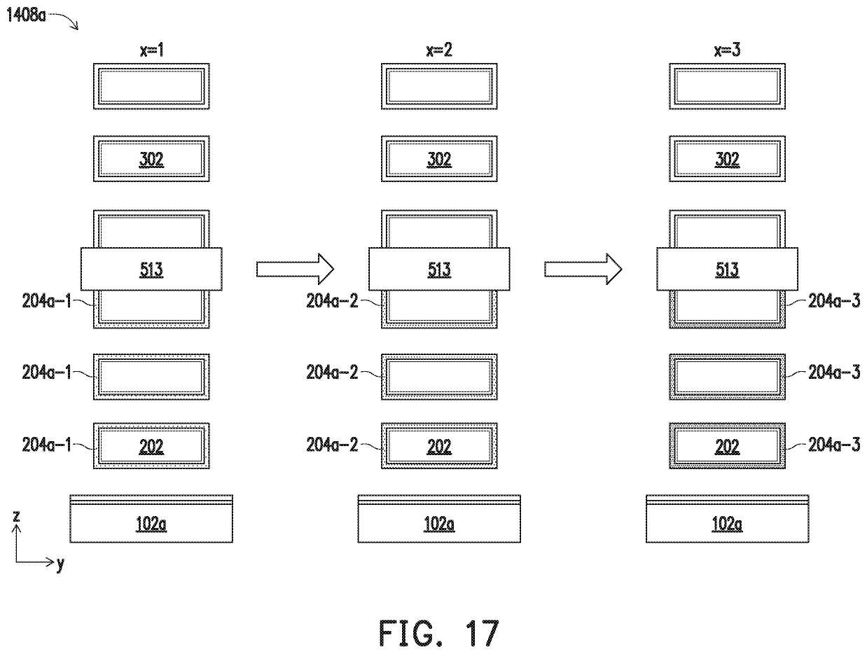

At the end of step 1026-6, a first loop of the first dipole loop process is finished. Referring now to FIG. 17, at the end of the first loop, gate dielectric layers 204a-1 are formed where the gate dielectric layers 204a-1 have a first concentration of dopants. Note that the first dipole loop process may iteratively repeat x number of times (e.g., x=3). As shown in FIG. 17, after each iterative dipole loop, more dopants are driven into the gate dielectric layers 204. For example, after a second dipole loop (e.g., x=2) of the first dipole loop process, gate dielectric layers 204a-2 are formed where the gate dielectric layers 204a-2 have a second concentration of dopants greater than the first concentration. And after a third dipole loop (e.g., x=3) of the first dipole loop process, gate dielectric layers 204a-3 are formed, where the gate dielectric layers 204a-3 have a third concentration of dopants greater than the second concentration. FIG. 17 shows the first dipole loop process performed 3 times in the CFET channel region 1408a, but the present disclosure is not limited thereto. With respect to the CFET channel region 1408a, depending on the dipole patterning process, the first dipole loop process may be performed any number of times or not performed at all. Note that each dipole loop may also vary in terms of temperature, anneal durations, dipole layer thickness, so as to result in different dipole drive-in amounts. For example, each additional loop drives in less dipole dopants than the previous loop by varying temperature, anneal durations, and dipole layer thickness.

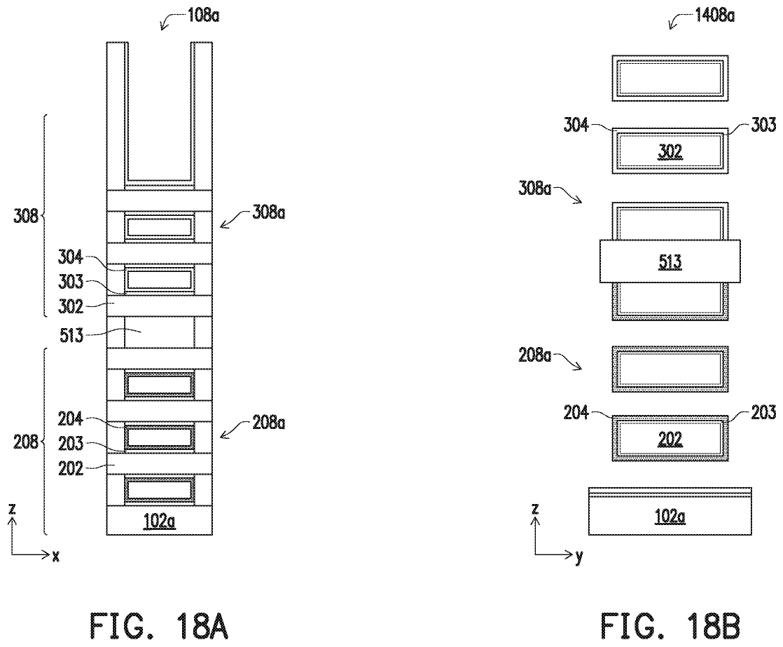

FIG. 18A illustrates an x cross-sectional view of the CFET gate region 108a after performing the first dipole loop process (operation 1026). The CFET gate region 108a corresponds to the CFET gate region 108a in FIG. 10, and the features will not be described again for the sake of brevity.

FIG. 18B illustrates a y cross-sectional view of the CFET channel region 1408a after performing the first dipole loop process (operation 1026). The channel region 1408a corresponds to the CFET channel region 1408a in FIG. 14B, and the similar features will not be described for the sake of brevity. The difference here is that the gate dielectric layers 204 are already doped by the first dipole loop process, for example, 3 times.

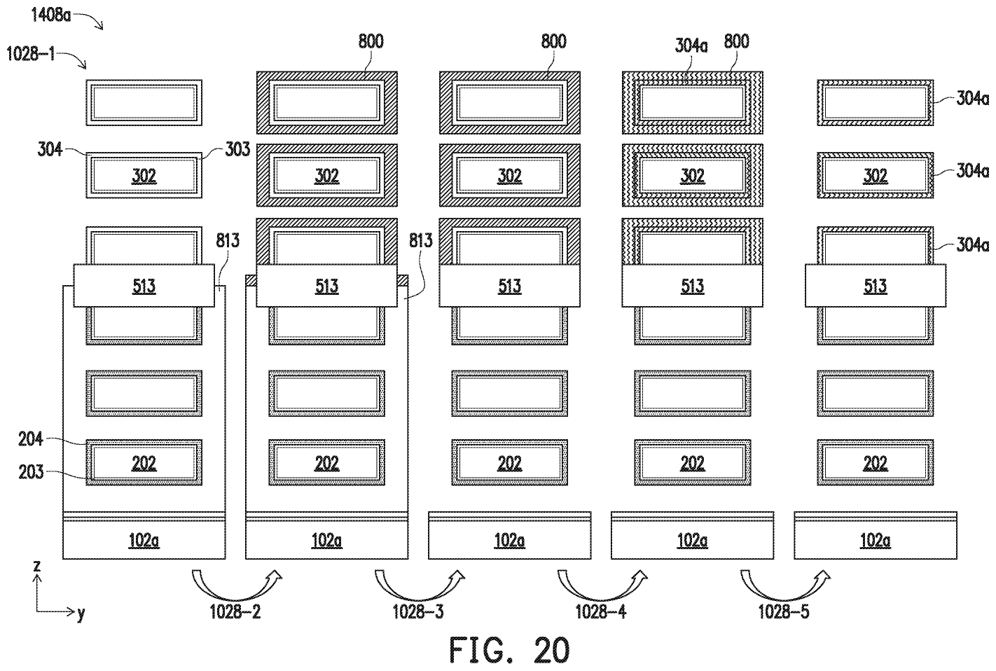

FIG. 19 is a flow chart of a method to perform a second dipole loop process. Specifically, FIG. 19 shows a flow chart of operation 1028 (described above), which is now broken into additional steps. The operation 1028 in FIG. 19 is described below in conjunction with FIG. 20, which illustrates y cross-sectional views of the CFET channel region 1408a at intermediate stages of fabrication and processed in accordance with the method of FIG. 19.

Now referring to FIG. 20, at step 1028-1, the operation 1028 forms a mask 813 (e.g., hard mask) over the bottom device (e.g., PFET device) but leaving the top device (E.g., NFET device) exposed. Specifically, the hard mask selectively covers all the gate dielectric layers 204 surrounding channel layers 202, which are below the channel isolation layer 513. At step 1028-2, the operation 1028 deposits second dipole dopant layers 800 (e.g., n-type dopant layers) over exposed gate dielectric layers 304 in the top device while the mask 813 covers the gate dielectric layers 204 in the bottom device. The second dipole dopant layers 800 wrap around the respective gate dielectric layers 304 in the CFET channel region 1408a. The second dipole dopant layer 800 may include n-type dipole dopants such as lanthanum. For example, the second dipole dopant layer 800 may be a lanthanum oxide layer. Due to the presence of the channel isolation layer 513, the second dipole dopant layer 800 may not completely wrap around the bottommost channel layer 302 (i.e., the bottom surface of the bottommost channel layer 302 is covered by the channel isolation layer 513). At step 1028-3, the operation 1028 removes the mask 813 by a suitable process. At step 1028-4, the operation 1028 performs annealing to drive dipole dopants (metal atoms) from the second dipole dopant layer 800 into the gate dielectric layers 304 and/or interfacial layers 303, thereby forming doped gate dielectric layers 304a. At step 1028-5, the operation 1028 removes the second dipole dopant layers 800 from the CFET channel region 1408a by etching.

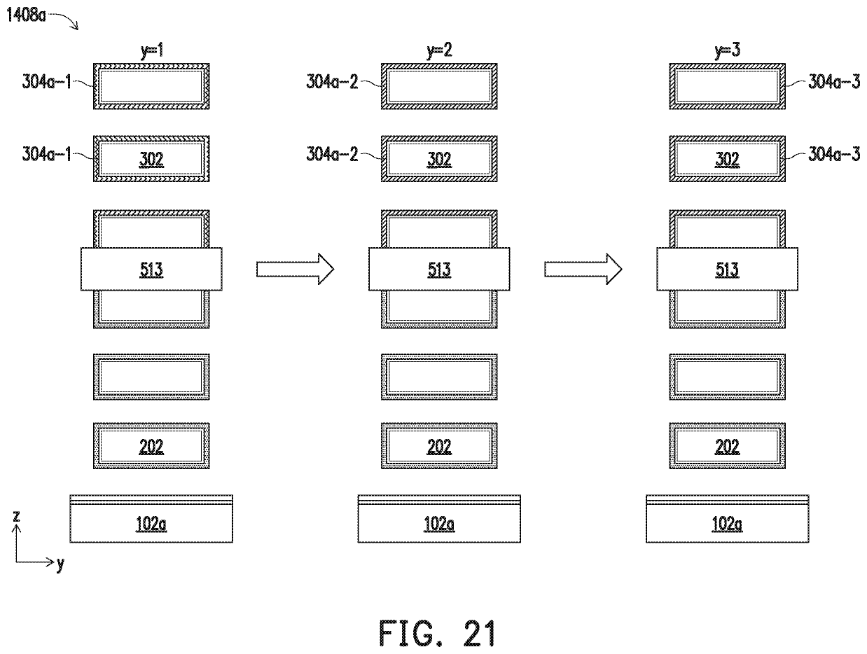

At the end of step 1028-5, a first loop of the second dipole loop process is finished. Referring now to FIG. 21, at the end of the first loop, gate dielectric layers 304a-1 are formed where the gate dielectric layers 304a-1 have a first concentration of dopants. Note that the second dipole loop process may iteratively repeat y number of times (e.g., y=3). As shown in FIG. 21, after each iterative dipole loop, more dopants are driven into the gate dielectric layers 304. For example, after a second dipole loop (e.g., y=2) of the second dipole loop process, gate dielectric layers 304a-2 are formed where the gate dielectric layers 304a-2 have a second concentration of dopants greater than the first concentration. And after a third dipole loop (e.g., y=3) of the second dipole loop process, gate dielectric layers 304a-3 are formed, where the gate dielectric layers 304a-3 have a third concentration of dopants greater than the second concentration. FIG. 21 shows the second dipole loop process performed 3 times in the CFET channel region 1408a, but the present disclosure is not limited thereto. With respect to the CFET channel region 1408a, depending on the dipole patterning process, the second dipole loop process may be performed any number of times or not performed at all. Note that each dipole loop may also vary in terms of temperature, anneal durations, dipole layer thickness, so as to result in different dipole drive-in amounts. For example, each additional loop drives in less dipole dopants than the previous loop by varying temperature, anneal durations, and dipole layer thickness.

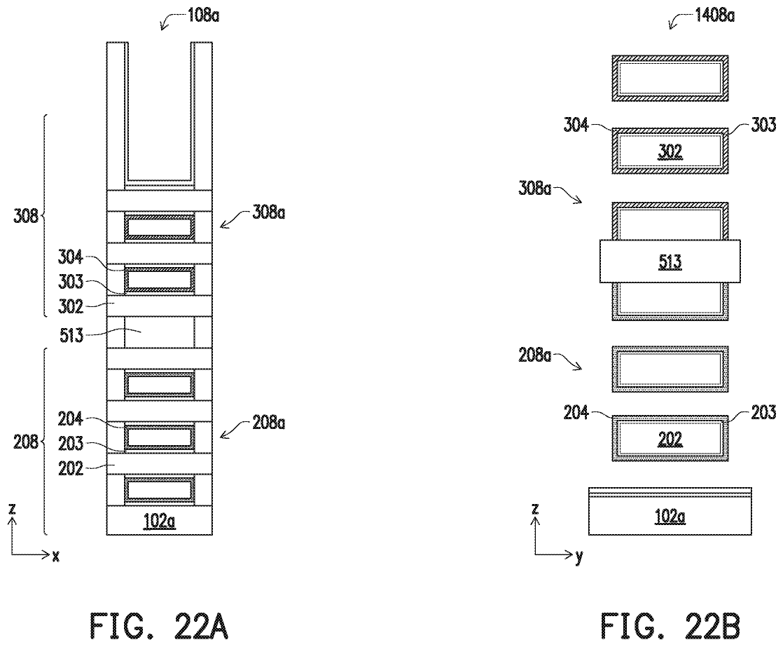

FIG. 22A illustrates an x cross-sectional view of the CFET gate region 108a after performing the second dipole loop process (operation 1028). The CFET gate region 108a corresponds to the CFET gate region 108a in FIG. 11, and the features will not be described again for the sake of brevity.

FIG. 22B illustrates a y cross-sectional view of the CFET channel region 1408a after performing the second dipole loop process (operation 1028). The channel region 1408a corresponds to the CFET channel region 1408a in FIG. 18B, and the similar features will not be described for the sake of brevity. The difference here is that the gate dielectric layers 304 are already doped by the second dipole loop process, for example, 3 times.

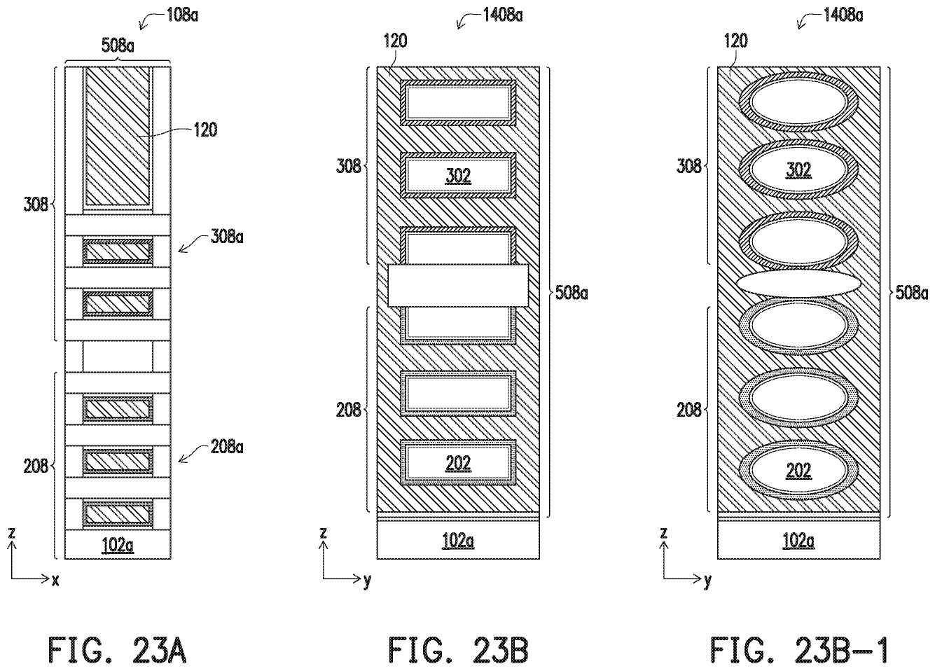

FIGS. 23A-23B illustrate x and y cross-sectional views of the CFET gate region 108a and the CFET channel region 1408a after depositing the gate metal 120 and forming the CFET metal gate structure 508a. The CFET metal gate structure 508a in FIG. 23A correspond to the CFET metal gate structure 508a in FIG. 12, and the features will not be described again for the sake of brevity. Referring to FIG. 23B, the channel region 1408a includes the gate metal 120 filling the voids between the channel layers 202/302. The same gate metal 120 surrounds the channel layers 202 and 302 in the respective PFET and NFET gate regions 208 and 308. Note that FIGS. 23A-23B show similar amounts of dopant concentration for the gate dielectric layers 204/304 in the PFET and NFET gate regions 208 and 308 (e.g., x=3 and y=3) but the present disclosure is not limited thereto.

The embodiments described thus far illustrate the channel layers 202/302 as nanosheet transistor channels with a rectangular shape. However, referring now to FIG. 23B-1, embodiments of this disclosure can equally apply to CFET devices having channel layers 202/302 having nanowire transistor channels. The nanowire transistor channels may have a circular or oval shape.

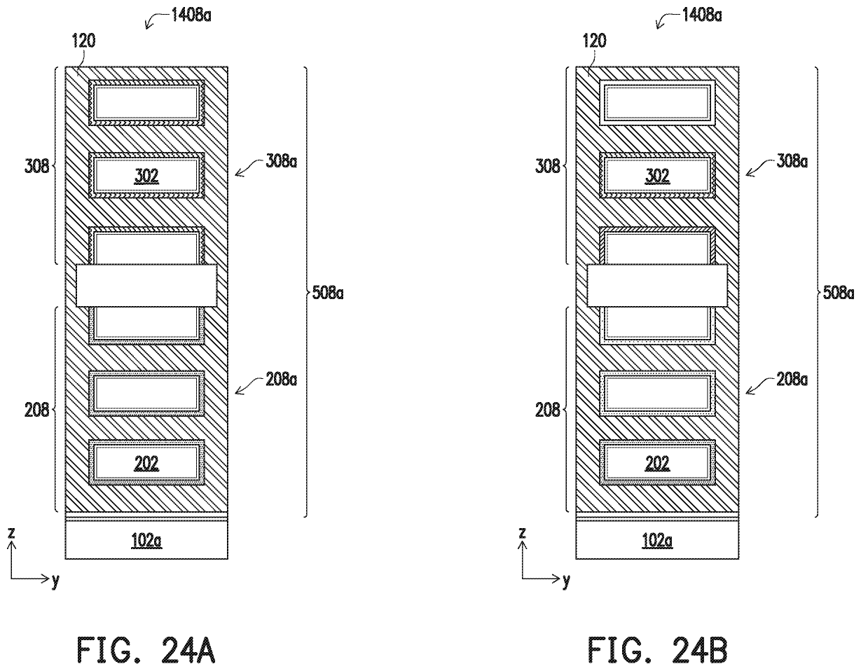

FIGS. 24A and 24B illustrate y cross-sectional views of other embodiments of the CFET channel region 1408a. FIGS. 24A and 24B are similar to FIG. 23A. The difference is how the gate dielectric layers 204/304 are doped by the first and second dipole loop processes. FIG. 24A shows different amounts of dopant concentration for gate dielectric layers 204/304 in the PFET and NFET gate regions (e.g., x=3, y=1). For example, the PFET device may go through more dipole loops than the NFET device within the same CFET device. For another example, FIG. 24B shows different amounts of dopant concentration for gate dielectric layers 204/304 within the same PFET gate regions 208 or within the same NFET gate regions 308. For example, individual channels 202/302 part of a same PFET or NFET device may have their gate dielectric layers 204/304 annealed different number of times. In other words, PFET and NFET devices vary in dopant concentration for each channel in a stack of channels. This allows for channel specific turn-on voltages within a same device, offering different threshold activation voltages for a single NFET or PFET. This can be achieved by the first and second loop processes described above, except that the mask 713 is fine tuned to cover specific channels in the bottom device, and the mask 813 is fine tuned to cover specific channels in the top device.

The first and second dipole loop processes allows for variation in dopants in a same CFET gate region 108 (e.g., CFET gate region 108a). This can be between PFET and NFET gate regions 208 and 308, between channels 202 of a same PFET gate region 208, or between channels 302 of a same NFET gate region 308. This type of variation is along the vertical direction for a same CFET gate structure 508 (e.g., CFET gate structure 508a). However, variation along the horizontal direction for different CFET gate structures 508a-508d is also possible through integrating a dipole patterning process with the first and second dipole loop processes. Dopant variations in the vertical and horizontal directions is desirable for optimizing the multi-Vt monolithic CFET device 100.

FIG. 25 is an exemplary diagram showing a first dipole patterning process 1100 that is used in conjunction with performing the first and/or second dipole loop processes in operations 1026/1028. Specifically, before each loop of the first or second dipole patterning process, the first dipole patterning process 1100 includes masking certain CFET gate regions 108 while exposing other CFET gate regions 108. FIG. 25 resembles a simplified version of FIG. 13. FIG. 25 shows a substrate 102 and channel regions 102a-102d part of the CFET gate regions 108a-108d. Over the channel regions 102a-102d are respective PFET or NFET channel layers 202/302, interfacial layers 203/303, and gate dielectric layers 204/304. And after performing N dipole loops, a gate metal 120 is deposited over the respective CFET gate regions 108a-108d. The N dipole loops may either be x number of loops from the first dipole loop process or y number of loops from the second dipole loop process. As shown, the 1^{st} loop DL1 of the N dipole loops is applied in the CFET gate region 108a but not in the CFET gate regions 108b-108d. For example, the CFET gate regions 108b-108d are masked when performing the 1^{st} loop DL1. Then, the 2^{nd} loop DL2 of the N dipole loops is applied in the CFET gate regions 108a and 108b but not in the CFET gate regions 108c-108d. For example, the CFET gate regions 108c-108d are masked when performing the 2^{nd} loop DL2. Then, the 3^{rd} loop DL3 of the N dipole loops is applied in the CFET gate regions 108a-108c but not in the CFET gate region 108d. For example, the CFET gate region 108d is masked when performing the 3^{rd} loop DL3. By the end of the 3^{rd} loop DL3, the CFET gate region 108a has gone through the first or second dipole loop process 3 times, the CFET gate region 108b has gone through the first or second dipole loop process 2 times, the CFET gate region 108c has gone through the first or second dipole loop process 1 time, and the CFET gate region 108d has gone through the first or second dipole loop process 0 times. The resulting structure is reflected in the embodiment of FIG. 1. Due to the number of loops performed, the dopant concentration varies from the CFET gate regions 108a-108d. In this case, 3 dipole loops are performed resulting in 4 different Vt across the CFET gate regions 108a-108d. Note that additional dipole loops may be performed in cases that have additional number of CFET gate regions. In any case, in the first dipole patterning process 1100 where N is the number of dipole loops, N=(N+1)(Vt). In other words, each loop increases one more Vt option. For example, 1 loop results in 2 Vts, 2 loops result in 3 Vts, 3 loops result in 4 Vts, and so on. Each Vt could be an NFET Vt or PFET Vt. Note also that in the first dipole patterning process 1100, after each N dipole loop, the number of CFET gate regions 108 being masked is decreased until only one CFET gate region 108 is masked. This may be done by removing portions of a same original hard mask from one end (e.g., right end) after each dipole loop.

FIG. 26 is an exemplary diagram showing a second dipole patterning process 1200 that is used in conjunction with performing the first and/or second dipole loop processes in operations 1026/1028. Specifically, before each loop of the first or second dipole patterning process, the second dipole patterning process 1200 includes masking certain CFET gate regions 108 while exposing other CFET gate regions 108. FIG. 26 shows a substrate 102 and channel regions 102a-102h part of the CFET gate regions 108a-108h. Over the channel regions 102a-102h are respective PFET or NFET channel layers 202/302, interfacial layers 203/303, and gate dielectric layers 204/304. And after performing N dipole loops, a gate metal 120 is deposited over the respective CFET gate regions 108a-108h. The N dipole loops may either be x number of loops from the first dipole loop process or y number of loops from the second dipole loop process. FIG. 26 illustrates an embodiment N=3 where 3 dipole loops are performed. As shown, the 1^{st} loop DL1 of the N dipole loops is applied in the CFET gate regions 108a-108d but not in the CFET gate regions 108e-108h. For example, the CFET gate regions 108e-108h are masked when performing the 1^{st} loop DL1. Then, the 2^{nd} loop DL2 of the N dipole loops is applied in the CFET gate regions 108a-108b and 108e-108f but not in the CFET gate regions 108c-108d and 108g-108h. For example, the CFET gate regions 108c-108d and 108g-108h are masked when performing the 2^{nd} loop DL2. Then, the 3^{rd} loop DL3 (or the nth loop) of the N dipole loops is applied in the CFET gate regions 108a, 108c, 108e, and 108g but not in the CFET gate region 108b, 108d, 108f, and 108h. For example, the CFET gate regions 108b, 108d, 108f, and 108h are masked when performing the 3^{rd} loop DL3. By the end of the 3^{rd} loop DL3, the CFET gate region 108a has gone through the loops DL1, DL2, and DL3, the CFET gate region 108b has gone through the loops DL1 and DL2, the CFET gate region 108c has gone through the loops DL1 and DL3, the CFET gate region 108d has gone through the loops DL1, the CFET gate region 108e has gone through the loops DL2 and DL3, the CFET gate region 108f has gone through the loops DL2, the CFET gate region 108g has gone through the loops DL3, and the CFET gate region 108h has not gone through any DL loops. Although some of the CFET gate regions 108a-108h experienced a same amount of dipole loops (e.g., CFET gate regions 108d and 108g both experienced one dipole loop), all the CFET gate regions experienced a different combination of the dipole loops (e.g., no two CFET gate regions experienced the same amount of the same dipole loop). For example, CFET gate regions 108d and 108g both experienced one dipole loop, but one experienced DL1 and the other experienced DL3.

By varying the amount of dopants driven into the gate dielectric layers in each applied loop (e.g., first loop drives more dopants, second loop drives less dopants, third loop drives even less dopants), here, 3 dipole loops are performed resulting in 8 different Vt across the CFET gate regions 108a-108h. Note that additional dipole loops may be performed in cases that have additional number of CFET gate regions. In any case, in the second dipole patterning process 1200 where N is the number of dipole loops, N=(2ⁿ)Vt. In other words, each loop doubles the Vt option (by patterning design). For example, 1 loop results in 2 Vts, 2 loops result in 4 Vts, 3 loops result in 8 Vts, and so on. Each Vt could be an NFET Vt or PFET Vt. As shown, integrating the first or second loop processes with the second dipole patterning process 1200 produces more threshold voltages per number of loops than integrating the first or second loop processes with the first dipole patterning process 1100.

The first and second dipole patterning processes 1100 and 1200 targets different CFET gate regions 108 in the x direction and can be achieved by any suitable lithography and patterning techniques. The patterning involved in the first and second dipole loop processes (operations 1026 and 1028) in the z direction can be achieved by the example processes as shown and described with respect to FIGS. 16 and 20. These combinations allows for dopant variations in the horizontal and vertical direction for the gate dielectric layers 204/304 of the monolithic CFET device 100.

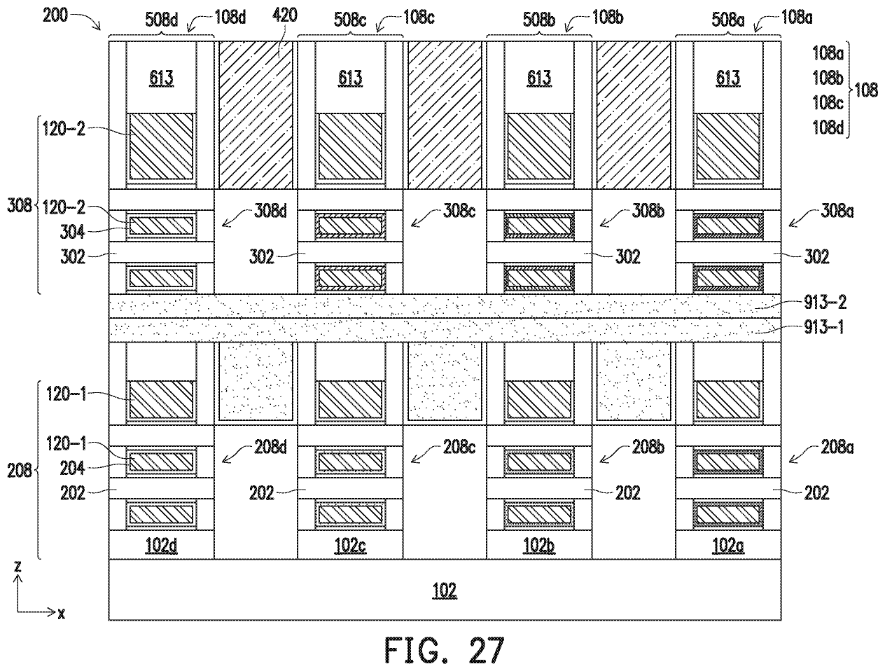

FIG. 27 illustrates a cross-sectional view of a sequential CFET semiconductor device 200 having multi Vt offerings. Like the monolithic CFET semiconductor device 100, the multi Vt offering is effectuated through iteratively doping respective gate dielectric layers 204 and/or 304 in different CFET gate regions 108. As an example embodiment, FIG. 27 shows four CFET gate regions 108a, 108b, 108c, and 108d over respective channel regions 102a, 102b, 102c, and 102d protruding from a substrate 102. Stacks of semiconductor channels 202 and/or 302 are disposed over respective channel regions 102a, 102b, 102c, and 102d. In each of the CFET gate regions 108, the semiconductor channels 202/302 are wrapped around and interposed by respective CFET metal gate structures 508a, 508b, 508c, and 508d, each having gate dielectric layers 204/304 and a metal gate electrode 120-1 or 120-2. A top portion of the metal gate electrode 120-2 is disposed over the topmost channels 302 of each stack.

The sequential CFET semiconductor device 200 is similar to the monolithic CFET semiconductor device 100, and the similar features will not be described again for the sake of brevity. The difference is that the bottom transistor region is formed separately from the top transistor region. Specifically, the bottom and top transistor regions are formed sequentially in different processing steps. As such, in the disclosed embodiment, PFET metal gate structures in the PFET gate regions 208 for PFET devices are completely formed before forming NFET metal gate structures in the NFET gate regions 308 for NFET devices. Here, the bottom transistor region includes PFET gate regions 208 for PFET devices, and the top transistor region includes NFET gate regions 308 for NFET devices. In other embodiments, the bottom transistor region may include NFET gate regions 308 for NFET devices, and the top transistor region may include PFET gate regions 208 for PFET devices.

Since the top and bottom transistor regions are formed separately, as will be described below, the method of performing the first and second loop processes is simplified, where each do not require the steps of selectively depositing dipole dopant layers in the PFET gate regions to the exclusion of the NFET gate regions, or depositing dipole dopant layers in the NFET gate regions to the exclusion of the PFET gate regions. This is because bottom PFET gate structures are completely formed, which include depositing the first gate metal 120-1, before forming top NFET gate structures, which include depositing the gate metal 120-2. Note that in the sequential CFET semiconductor device 200, the PFET gate regions 208 are separated from the NFET gate regions 308 by bonding dielectric layers 913-1 and 913-2. The bonding dielectric layers 913-1 and 913-2 also separate S/D features contacting the channel layers 202 from S/D features contacting the channel layers 302. In other respects, such as concerning the dipole dopant concentrations in the different gate dielectric layers 302/304, the sequential CFET semiconductor device 200 is similar to what has been described with respect to the monolithic CFET semiconductor device 100.

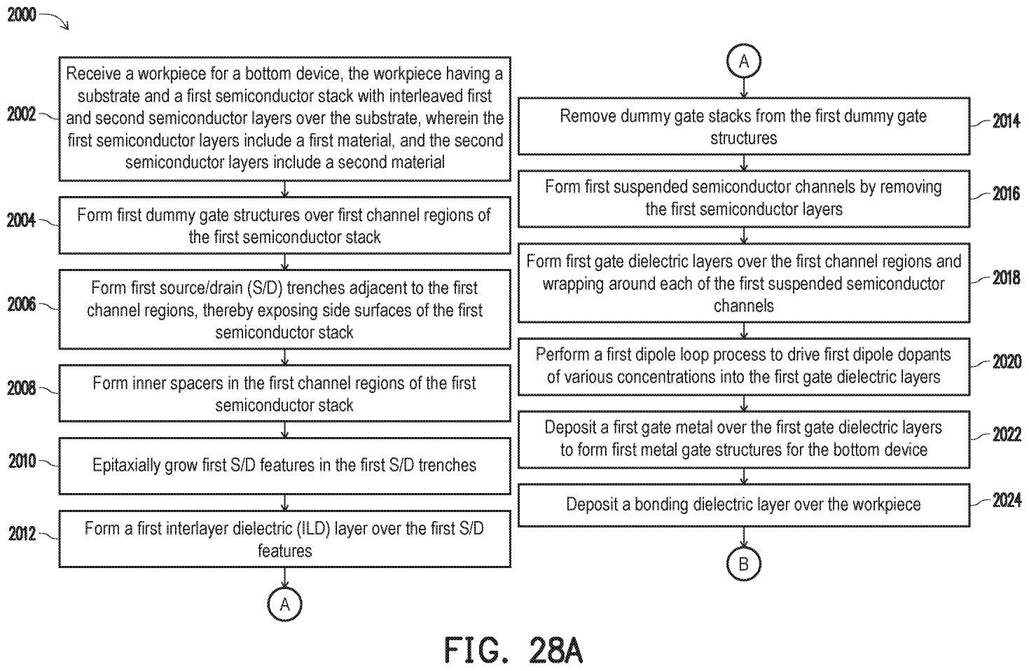

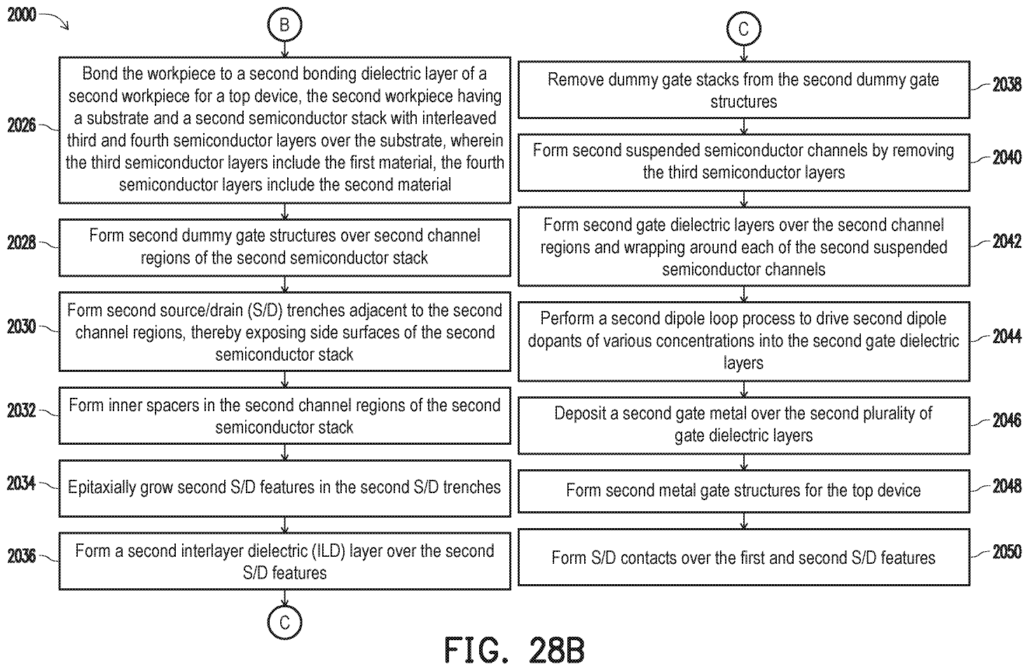

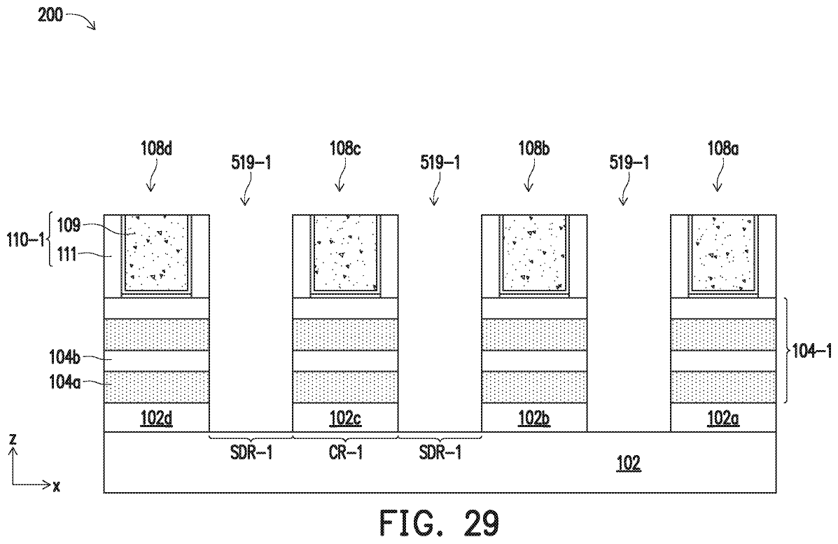

FIGS. 28A-28B is a flow chart of a method 2000 to form a sequential CFET semiconductor device 200 having multi Vt offerings, in portion or in entirety, according to various aspects of the present disclosure. The method 2000 is described below with reference to FIGS. 29-41, which illustrate cross-sectional views of a sequential CFET semiconductor device 200 at intermediate stages of fabrication. In method 2000, the first and second dipole loop processes are separately applied in the bottom transistor region and the top transistor region. Also in method 2000, the depositing of the respective gate metals 120-1 and 120-2 are separately performed over the bottom transistor region and top transistor region. This is because bottom devices in the bottom transistor region is completely formed first, then top devices in the top transistor region is formed over it after a flip and bond process. Unless noted otherwise, details of relevant features described with respect to FIGS. 3-13 of the monolithic CFET device 100 may equally apply to the sequential CFET device 200 in FIGS. 29-41.

Referring to FIG. 29, the method 2000 at operation 2002 receives a workpiece for a bottom device, the workpiece having a substrate 102 and a first semiconductor stack 104-1 with interleaved first and second semiconductor layers 104a and 104b over the substrate 102. The first semiconductor layers 104a include a first material (e.g., germanium), and the second semiconductor layers include a second material (e.g., silicon). For example, the first semiconductor layers 104a are silicon germanium layers and the second semiconductor layers 104b are silicon layers. The first semiconductor stack 104-1 for the sequential CFET semiconductor device 200 may have fewer semiconductor layers than the semiconductor stack 104 for the monolithic CFET semiconductor device 100. Also note that unlike the monolithic CFET semiconductor device 100, the sequential CFET semiconductor device 200 does not have a middle layer 107 having a greater concentration of the second material (e.g., germanium).

Still referring to FIG. 29, the method 2000 at operation 2004 forms first dummy gate structures 110-1 over first channel regions CR-1 of the first semiconductor stack 104-1. The first dummy gate structures 110-1 includes dummy gate stacks 109 and gate spacers 111. Still referring to FIG. 29, the method 2000 at operation 2006 forms first source/drain (S/D) trenches 519-1 in the first S/D regions SDR-1 adjacent to the first channel regions CR-1, thereby exposing side surfaces of the first semiconductor stack 104-1. As part of forming the trenches 519-1, portions of the substrate 102 are also recessed, thereby forming the channel regions 102a-102d in respective first channel regions CR-1.

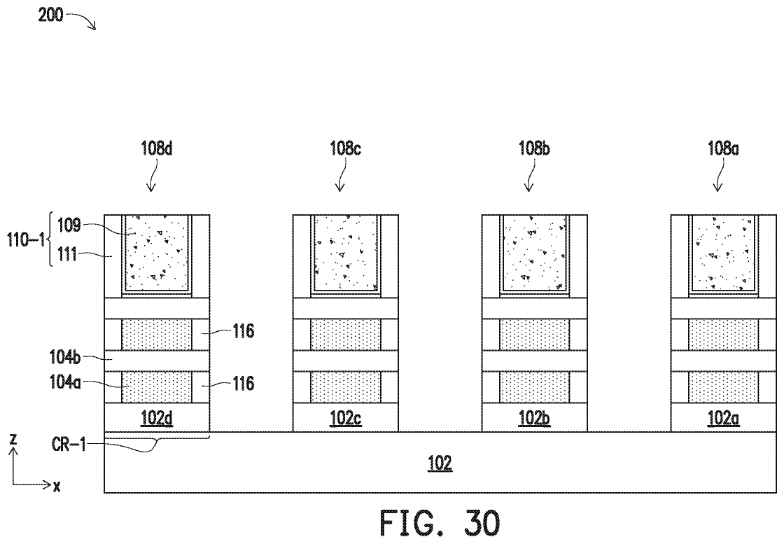

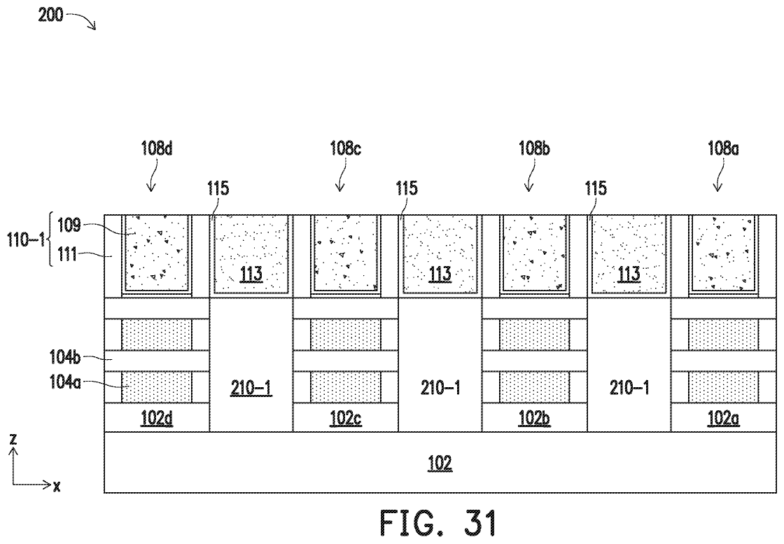

Now referring to FIG. 30, the method 2000 at operation 2008 forms inner spacers 116 in the first channel regions CR-1 of the first semiconductor stack 104-1. Now referring to FIG. 31, the method 2000 at operation 2010, epitaxially grows first S/D features 210-1 in the first S/D trenches 519-1, which corresponds to S/D features for the bottom devices (e.g., p-type S/D features). Still referring to FIG. 31, the method 2000 at operation 2012 forms a first interlayer dielectric (ILD) layer 113 over the first S/D features 210-1. The first ILD layer 113 may be formed over an etch stop layer 115 over the first S/D features 210-1.

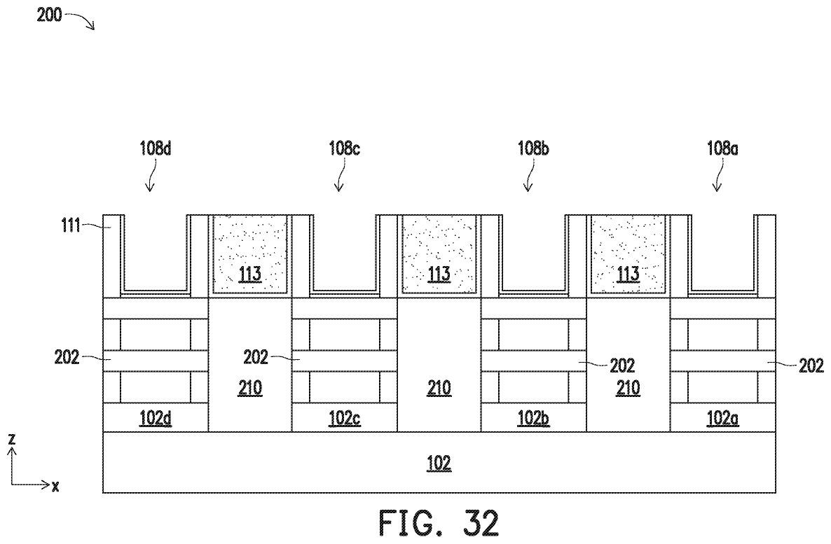

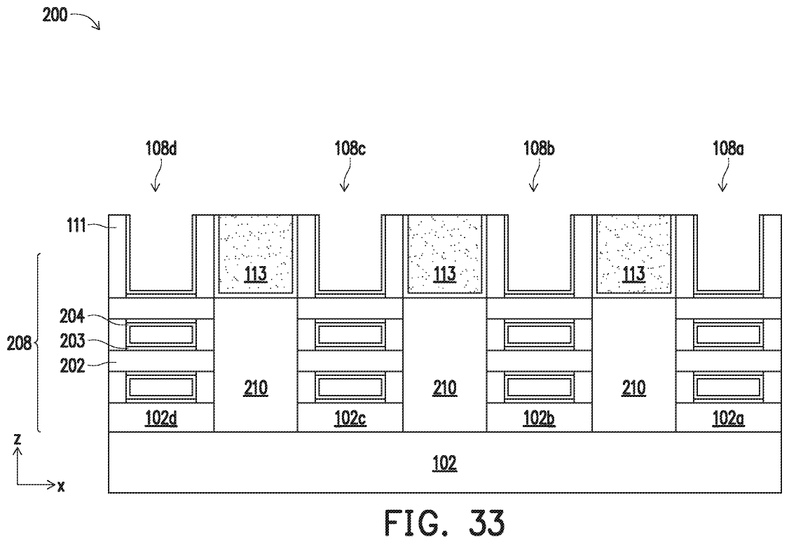

Now referring to FIG. 32, the method 2000 at operation 2014 removes the dummy gate stacks 109 from the first dummy gate structures 110-1. Still referring to FIG. 32, the method at operation 2016 forms first suspended semiconductor channels 202 by removing the first semiconductor layers 104a. The first suspended semiconductor channels 202 refer to channel layers for the bottom transistor devices (e.g., PFET channels of the CFET device 200). Now referring to FIG. 33, the method 2000 at operation 2018 forms first gate dielectric layers 204 over the respective channel regions 102a-102d and wrapping around each of the first suspended semiconductor channels 202. In an embodiment, interfacial layers 203 are formed over the first suspended semiconductor channels 202 before forming the first gate dielectric layers 204. The bottom gate region (e.g., PFET gate region 208) includes the first suspended semiconductor channels 202, the interfacial layers 203, and the first gate dielectric layers 204.

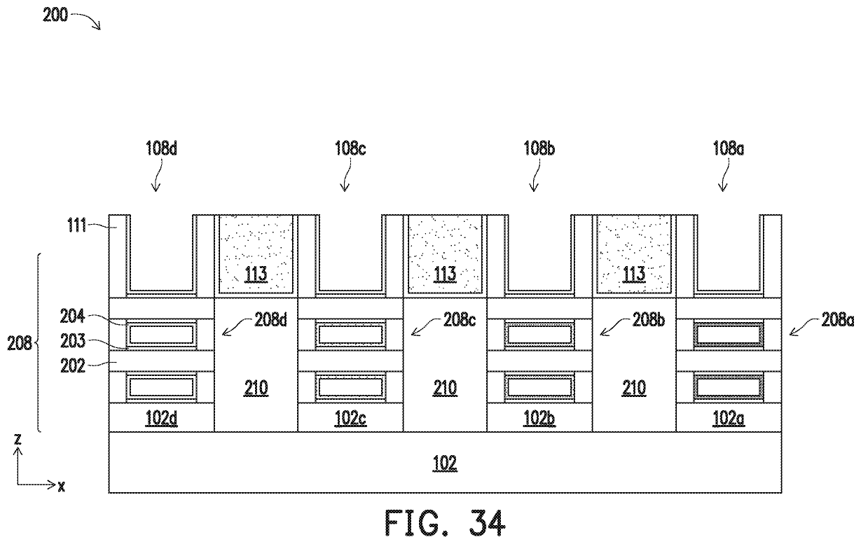

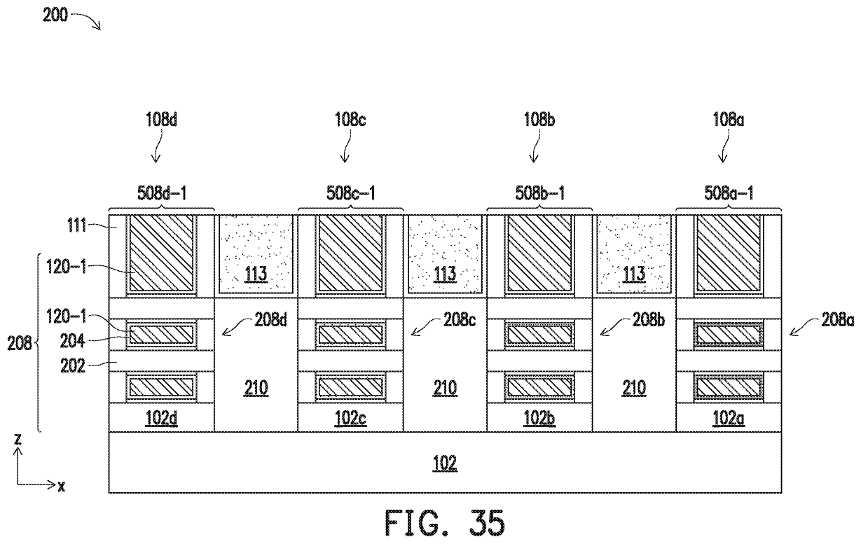

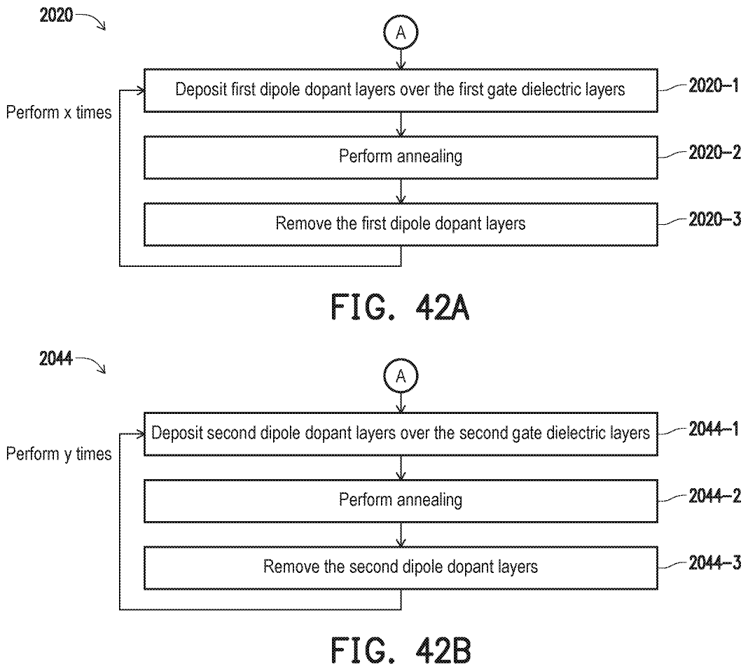

Now referring to FIG. 34, the method 2000 at operation 2020 performs a first dipole loop process to drive first dipole dopants of various concentrations into the first gate dielectric layers 204. This operation is further described in more detail with respect to FIG. 42A, which involves annealing dipole dopant layers of a first conductivity type (e.g., p-type) to drive first dopants (e.g., zinc) into the gate dielectric layers 204. Referring to FIG. 42A, the operation 2020 is further broken down into steps 2020-1, 2020-2, and 2020-3. Step 2020-1 deposits first dipole dopant layers (e.g., zinc oxide layers) over the first gate dielectric layers 204. Step 2020-2 performs annealing to drive the first dipole dopants (e.g., zinc) into the gate dielectric layers 204. Step 2020-3 removes the first dipole dopant layers. Note that this operation of performing a first dipole loop process is simpler than the one performed for a monolithic CFET device. This is because no hard mask processes are needed to isolate PFET gate dielectric layers 204 from NFET gate dielectric layers 304 for selective dipole drive-in during annealing. The operation 2020 may repeat for x number of times where x may be different depending on the dipole patterning processes (see FIGS. 25-26). For example, the operation 2020 is performed 3 times, resulting in the dopant concentration profile of FIG. 34. This is the result of performing the first dipole loop process 3 times in the PFET gate regions 208a, 2 times in the PFET gate region 208b, 1 time in the PFET gate region 208c, and 0 times in the PFET gate region 208d. Note that although selective dipole drive-in between PFET and NFET gate regions 208 and 308 are not needed (since NFET gate regions will be formed later), selective dipole drive-in of gate dielectric layers 204 between channel layers 202 within the same PFET channel regions is still possible in an embodiment (e.g., by applying FIG. 24B and the accompanying disclosure).

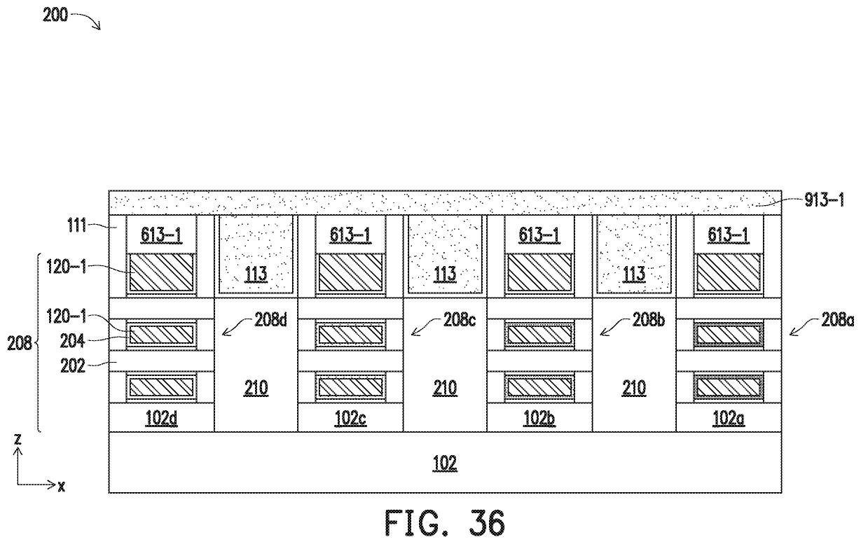

Now referring to FIG. 35, the method 2000 at operation 2022 deposits a first gate metal 120-1 over the first gate dielectric layers 204 to form first metal gate structures 508a-1 to 508d-1 for the bottom device (e.g., PFETs). Now referring to FIG. 36, the method 2000 at operation 2024 deposits a bonding dielectric layer 913-1 over the workpiece. This may be done after forming first gate dielectric caps 613-1 as shown. The bonding dielectric layer 913-1 directly contacts the first gate dielectric caps 613-1, the gate spacers 111, and the first ILD layer 113.

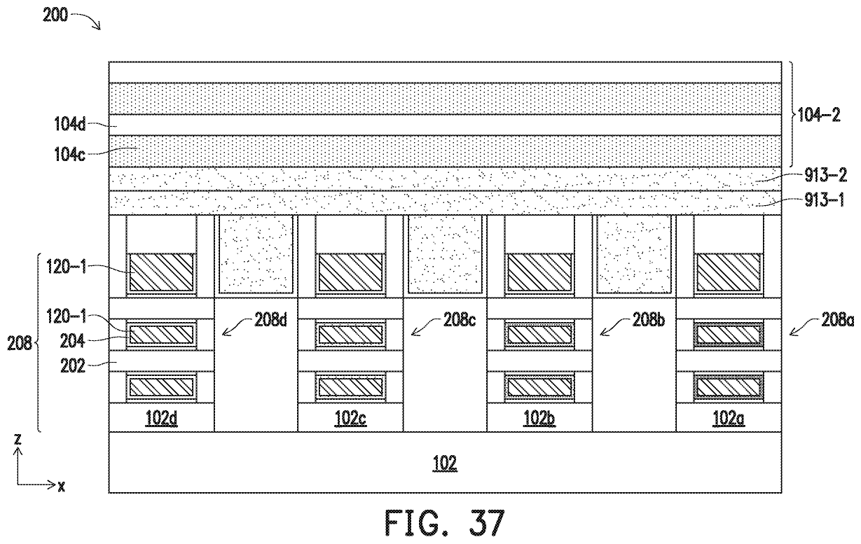

Now referring to FIG. 37, the method 2000 at operation 2026 bonds the workpiece to a second bonding dielectric layer 913-2 of a second workpiece for a top device (e.g., NFETs). The second workpiece has a substrate (not shown) and a second semiconductor stack 104-2 with interleaved third and fourth semiconductor layers 104c and 104d over the substrate, wherein the third semiconductor layers include the first material (e.g., germanium), and the fourth semiconductor layers include the second material (e.g., silicon). The second semiconductor stack 104-2 for the sequential CFET semiconductor device 200 may have fewer semiconductor layers than the semiconductor stack 104 for the monolithic CFET semiconductor device 100. The third semiconductor layers 104c may be silicon germanium layers, and the fourth semiconductor layers 104d may be silicon layers. Note that the second workpiece is first formed separately, then it is flipped over for bonding with the first workpiece. Before the second workpiece is flipped over, the second bonding dielectric layer 913-2 is formed over the second semiconductor stack 104-2. And after flipping the second workpiece over, the first and second workpieces are bonded together through the first and second bonding dielectric layers 913-1 and 913-2. After the bonding, the top device (i.e., second workpiece) is thinned down through a thin-down process (such as by etching) to remove excess substrate portions, or the top device is thinned down through a de-bonding process that separates the excess substrate portions from the second semiconductor stack 104-2.

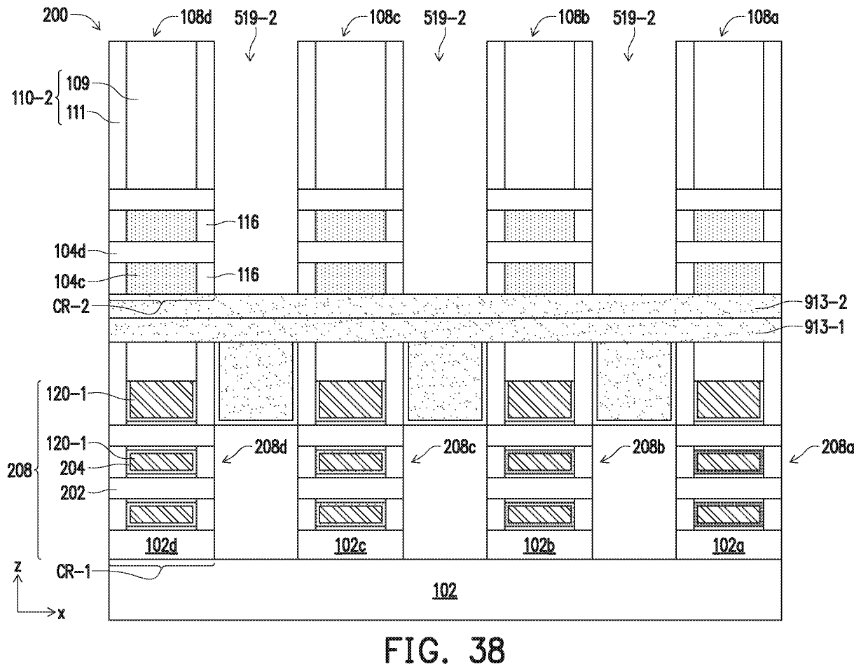

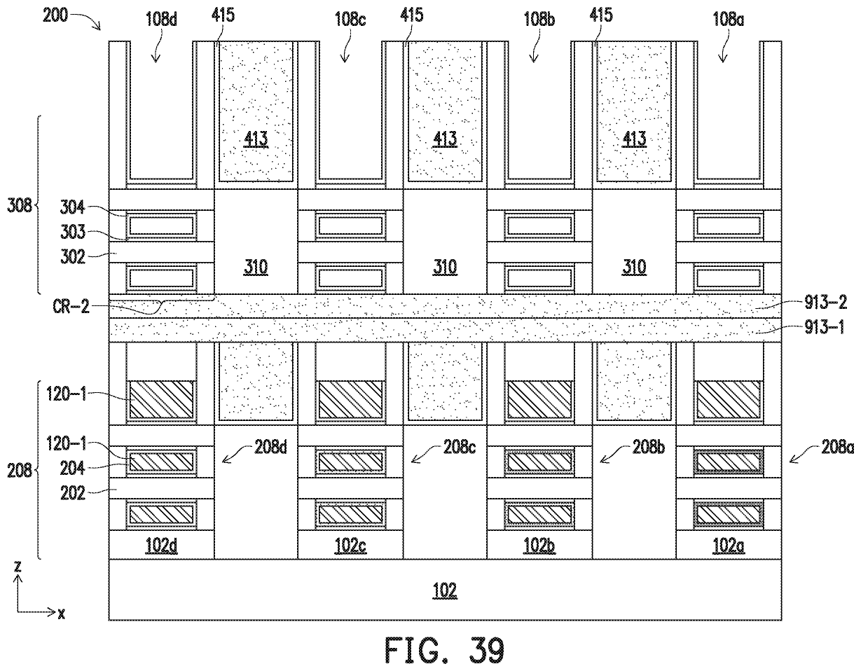

Now referring to FIGS. 38-41, the method 2000 performs similar method steps to form the top devices (NFETs) as the method steps previously described to form the bottom devices (PFETs). These steps are briefly described below. As shown in FIG. 38, the method 2000 at operation 2028 forms second dummy gate structures 110-2 over second channel regions CR-2 of the second semiconductor stack 104-2. Still referring to FIG. 38, the method 2000 at operation 2030 forms second source/drain (S/D) trenches 519-2 adjacent to the second channel regions CR-2, thereby exposing side surfaces of the second semiconductor stack 104-2. Still referring to FIG. 38, the method 2000 at operation 2032 forms inner spacers 116 in the second channel regions CR-2 of the second semiconductor stack 104-2. Now referring to FIG. 39, the method 2000 at operation 2034 epitaxially grow second S/D features 310 in the second S/D trenches 519-2, which corresponds to S/D features for the bottom transistors (e.g., n-type S/D features). Still referring to FIG. 39, the method 2000 at operation 2036 forms a second interlayer dielectric (ILD) layer 413 over the second S/D features 310. Still referring to FIG. 39, the method 2000 at operation 2038 removes dummy gate stacks 109 from the second dummy gate structures 110-2. Still referring to FIG. 39, the method 2000 at operation 2040 forms second suspended semiconductor channels 302 by removing the third semiconductor layers 104c. The suspended semiconductor channels 302 refer to channel layers for the top transistor devices (e.g., NFET channels of the CFET device 200). Still referring to FIG. 39, the method 2000 at operation 2042 forms second gate dielectric layers 304 over the second channel regions CR-2 and wrapping around each of the second suspended semiconductor channels 302.

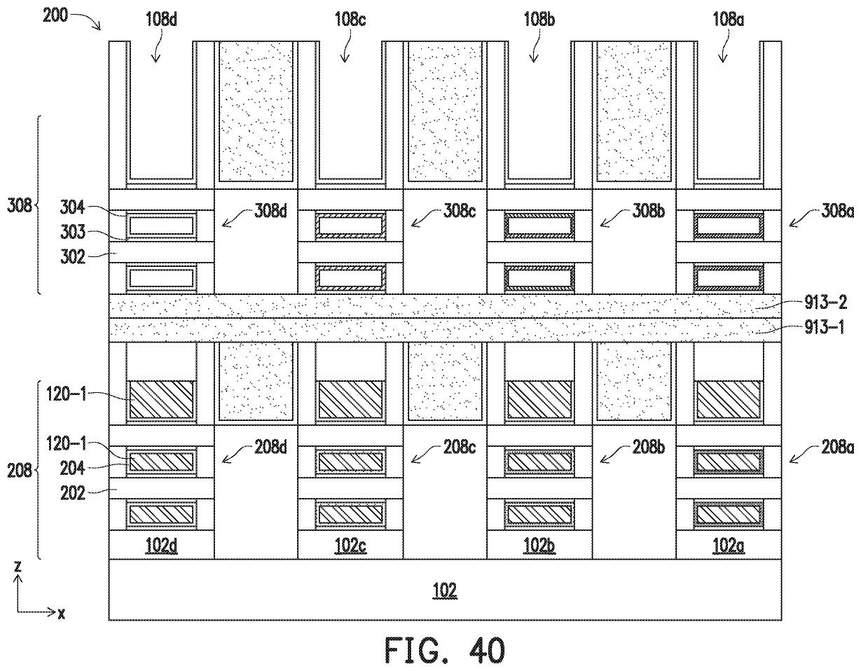

Now referring to FIG. 40, the method 2000 at operation 2044 performs a second dipole loop process to drive second dipole dopants of various concentrations into the second gate dielectric layers 304. This operation is further described in more detail with respect to FIG. 42B, which involves annealing dipole dopant layers of a second conductivity type (e.g., n-type) to drive second dopants (e.g., lanthanum) into the gate dielectric layers 304. Referring to FIG. 42B, the operation 2044 is further broken down into steps 2044-1, 2044-2, and 2044-3. Step 2044-1 deposits second dipole dopant layers (e.g., lanthanum oxide layers) over the second gate dielectric layers 304. Step 2044-2 performs annealing to drive the second dipole dopants (e.g., lanthanum) into the gate dielectric layers 304. Step 2044-3 removes the second dipole dopant layers. Note that this operation of performing a second dipole loop process is simpler than the one performed for a monolithic CFET device. This is because no hard mask processes are needed to isolate PFET gate dielectric layers 204 from NFET gate dielectric layers 304 for selective dipole drive-in during annealing. The operation 2044 may repeat for y number of times where y may be different depending on the dipole patterning processes (see FIGS. 25-26). For example, the operation 2044 is performed 3 times, resulting in the dopant concentration profile of FIG. 40. This is the result of performing the second dipole loop process 3 times in the NFET gate regions 308a, 2 times in the NFET gate region 308b, 1 time in the NFET gate region 308c, and 0 times in the NFET gate region 308d. Note that although selective dipole drive-in between PFET and NFET gate regions 208 and 308 are not needed (since PFET gate regions already formed their gate structures), selective dipole drive-in of gate dielectric layers 304 between channel layers 302 within the same NFET channel regions is still possible in an embodiment (e.g., by applying FIG. 24B and the accompanying disclosure).

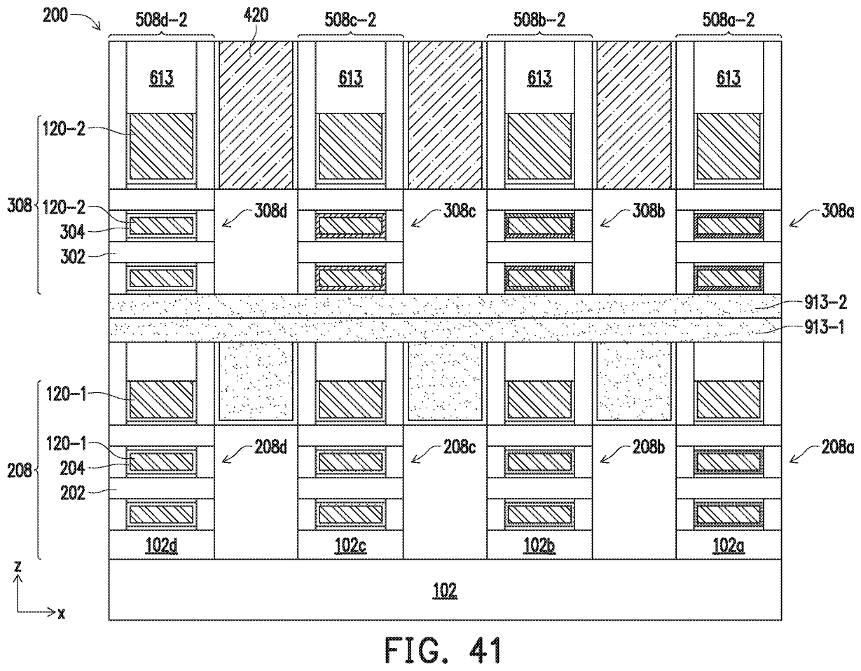

Now referring to FIG. 41, the method 2000 at operations 2046/2048 deposits a second gate metal 120-2 over the second gate dielectric layers 304 to form second metal gate structures 508a-2 to 508d-2 for the top device (e.g., NFETs). Note that the first metal gate structures 508a-1 to 508d-1 and the second metal gate structures 508a-2 to 508d-2 collectively form the respective CFET metal gate structures 508a-508d (see FIG. 27). The first and second gate metals 120-1 and 120-2 may be of the same or different material composition. Unlike in the method 1000 described for a monolithic CFET device 100, the first and second gate metals 120-1 and 120-2 need not be of the same composition since they are formed in different processes. Still referring to FIG. 41, the method 2000 at operation 2050 forms S/D contacts 420 over the first and second S/D features 210/310.

The method 2000 may perform further steps to complete fabrication of the device 200. Additional processing such as forming metal vias and interconnects (not shown) is contemplated by the present disclosure. Additional operations can be provided before, during, and after method 2000, and some of the operations described can be moved, replaced, or eliminated for additional embodiments of method 2000.

Although not limiting, the present disclosure offers advantages for tuning CFET semiconductor devices to have multiple threshold voltages (Vt). One example advantage is tuning Vt without varying metal gate structure dimensions from one device to another. Instead, dipole loop processes are used to iteratively anneal and remove dopant layers in different gate regions of the CFET device. Another example advantage is that PFET and NFET gate regions in a same CFET may be doped differently to have different materials and different amounts of dopants. Another example advantage is that gate regions within a same NFET or PFET of a CFET may be doped differently from channel to channel, offering different threshold activation voltages for a single NFET or PFET. Another example advantage is the flexibility to vary dopant concentration in different gate regions in a horizontal and a vertical direction of the CFET.

One aspect of the present disclosure pertains to a method of forming a semiconductor device. The method includes forming a CFET structure having a bottom gate region having a first plurality of gate dielectric layers wrapping around a first plurality of channels and a top gate region having a second plurality of gate dielectric layers wrapping around a second plurality of channels. The method includes performing a first dipole loop process to drive first dipole dopants into the first plurality of gate dielectric layers. The first dipole loop process includes iteratively depositing first dipole dopant layers over the first plurality of gate dielectric layers, perform annealing to the first plurality of gate dielectric layers, and removing the first dipole dopant layers. A first gate dielectric layer of the first plurality of gate dielectric layers is annealed one time and a second gate dielectric layer of the first plurality of gate dielectric layers is annealed two times. The method includes performing a second dipole loop process to drive second dipole dopants into the second plurality of gate dielectric layers. The second dipole loop process includes iteratively depositing second dipole dopant layers over the second plurality of gate dielectric layers, perform annealing to the second plurality of gate dielectric layers, and removing the second dipole dopant layers, and wherein a third gate dielectric layer of the second plurality of gate dielectric layers is annealed one time and a fourth gate dielectric layer of the second plurality of gate dielectric layers is annealed two times. And after performing the first and second dipole loop processes, the method includes depositing a gate metal over the first and second plurality of gate dielectric layers.

In an embodiment, the first dipole dopants include lanthanum, and the second dipole dopants include zinc.

In an embodiment, before performing the annealing to the first plurality of gate dielectric layers, the first dipole loop process further includes: depositing the first dipole dopant layers over the second plurality of gate dielectric layers; forming a hard mask over the bottom gate region but leaving the top gate region exposed, where the hard mask covers first dipole dopant layers over the first plurality of gate dielectric layers while exposing first dipole dopant layers over the second plurality of gate dielectric layers; removing the first dipole dopant layers over the second plurality of gate dielectric layers; and removing the hard mask.

In an embodiment, before performing the annealing to the second plurality of gate dielectric layers, the second dipole loop process further includes: forming a hard mask over the bottom gate region but leaving the top gate region exposed, the hard mask covers the first plurality of gate dielectric layers while exposing the second plurality of gate dielectric layers; depositing the second dipole dopant layers over the hard mask when depositing the second dipole dopant layers over the second plurality of gate dielectric layers; and removing the hard mask.

In an embodiment, the method further includes a dipole patterning process, the dipole patterning process includes masking the CFET structure before performing each dipole loop of the first or the second dipole loop processes. For example, before performing a first dipole loop, the dipole patterning process exposes a first portion of the CFET structure, the first portion includes a first CFET device gate region having the second and the fourth gate dielectric layers. And before performing a second dipole loop, the dipole patterning process exposes a second portion of the CFET structure, second portion includes the first CFET device gate region having the second and the fourth gate dielectric layers and a second CFET device gate region having the first and third gate dielectric layers.

In a further embodiment, performing the first or second dipole loop process in combination with the dipole patterning process results in multiple gate threshold voltages in the CFET structure, where performing n dipole loops results in (n+1) gate threshold voltages.

In an embodiment, the method further comprises a dipole patterning process, the dipole patterning process includes masking the CFET structure before performing each dipole loop of the first or the second dipole loop processes. For example, before performing a first dipole loop, the dipole patterning process exposes a first portion of the CFET structure, the first portion includes a first CFET device gate region having the second and the fourth gate dielectric layers and a second CFET device gate region having the first and third gate dielectric layers. And before performing a second dipole loop, the dipole patterning process exposes a second portion of the CFET structure, the second portion includes the first CFET device gate region having the second and the fourth gate dielectric layers.

In a further embodiment, performing the first or second dipole loop process in combination with the dipole patterning process results in multiple gate threshold voltages in the CFET structure, wherein performing n dipole loops results in (2ⁿ) gate threshold voltages.

Another aspect of the present disclosure pertains to a method of forming a semiconductor device. The method includes receiving a workpiece having a substrate and a semiconductor stack with interleaved first and second semiconductor layers over the substrate. The first semiconductor layers include a first material, and the second semiconductor layers include a second material. The method includes forming dummy gate stacks over channel regions of the semiconductor stack. The method includes forming source/drain (S/D) trenches adjacent to the channel regions, thereby exposing side surfaces of the semiconductor stack. The method includes epitaxially growing first S/D features in the S/D trenches. The method includes forming an S/D isolation layer over the first S/D feature. The method includes epitaxially growing second S/D features in the S/D trenches and over the S/D isolation layer. The method includes forming an interlayer dielectric (ILD) layer over the second S/D features. The method includes removing the dummy gate stacks. The method includes forming suspended semiconductor channels by removing the first semiconductor layers. The method includes forming gate dielectric layers over the channel regions and wrapping around each of the suspended semiconductor channels. The method includes performing a first dipole loop process to drive first dipole dopants of various concentrations into a first plurality of the gate dielectric layers. The method includes performing a second dipole loop process to drive second dipole dopants of various concentrations into a second plurality of the gate dielectric layers. And the method includes depositing a gate metal over the first and second plurality of the gate dielectric layers.

In an embodiment, the first dipole loop process includes iteratively performing at least two times: depositing first dipole dopant layers over the gate dielectric layers, the gate dielectric layers include a first plurality of gate dielectric layers over semiconductor channels for a top device and a second plurality of gate dielectric layers over semiconductor channels for a bottom device; forming a hard mask over the bottom device but leaving the top device exposed; removing the first dipole dopant layers over the top device; removing the hard mask; annealing to drive the first dipole dopants into the first plurality of gate dielectric layers; and removing the first dipole dopant layers.

In an embodiment, the second dipole loop process includes iteratively performing at least two times: forming a hard mask over the bottom device but leaving the top device exposed; depositing second dipole dopant layers over exposed gate dielectric layers in the top device while the hard mask covers the gate dielectric layers in the bottom device; removing the hard mask; annealing to drive the second dipole dopants into the second plurality of gate dielectric layers; and removing the second dipole dopant layers.

Another aspect of the present disclosure pertains to a semiconductor device. The semiconductor device includes a first CFET having a first n-type field-effect transistor (NFET) and a first p-type field-effect transistor (PFET) directly above or below the first NFET. The first NFET has a first NFET channel and a first NFET gate dielectric layer around the first NFET channel, and the first PFET has a first PFET channel and a first PFET gate dielectric layer around the first PFET channel. The semiconductor device includes a second CFET having a second NFET and a second PFET directly above or below the second NFET. The second NFET has a second NFET channel and a second NFET gate dielectric layer around the second NFET channel, and the second PFET has a second PFET channel and a second PFET gate dielectric layer around the second PFET channel. The semiconductor device includes a gate metal electrode directly on the first and second NFET gate dielectric layers and the first and second PFET gate dielectric layers. The first and second NFET gate dielectric layers include an n-type dopant, and the first and second PFET gate dielectric layers include a p-type dopant different from the n-type dopant. The first NFET gate dielectric layer has a different amount of the n-type dopant from that of the second NFET, and the first PFET gate dielectric layer has a different amount of the p-type dopant than that of the second PFET gate dielectric layer.

In an embodiment, the n-type dopant includes lanthanum, and the p-type dopant includes zinc.

In an embodiment, the first NFET gate dielectric layer surrounds a first portion of the gate metal electrode, and the second NFET gate dielectric layer surrounds a second portion of the gate metal electrode. The first and second portions of the gate metal electrode have substantially the same thickness.

In an embodiment, the first NFET gate dielectric layer surrounds a first portion of the gate metal electrode, the first PFET gate dielectric layer surrounds a second portion of the gate metal electrode, and the first and second portions of the gate metal electrode have substantially the same thickness.

In an embodiment, the first NFET gate dielectric layer is a gate dielectric layer wrapping around one NFET channel of a first vertical stack of NFET channels, and the first NFET gate dielectric layer has a greater amount of the n-type dopant than another NFET gate dielectric layer wrapping around another NFET channel of the first vertical stack of NFET channels.

In an embodiment, the first PFET gate dielectric layer is a gate dielectric layer wrapping around one PFET channel of a first vertical stack of PFET channels, and the first PFET gate dielectric layer has a greater amount of the p-type dopant than another PFET gate dielectric layer wrapping around another PFET channel of the first vertical stack of PFET channels.

In an embodiment, the semiconductor device further includes: a first source/drain (S/D) feature disposed between the first NFET channel and the second NFET channel; a second S/D feature disposed between the first PFET channel and the second PFET channel; an S/D isolation layer separating the first S/D feature from the second S/D feature, the S/D isolation layer disposed directly between the first and second S/D features along a vertical direction; a first channel isolation layer separating the first NFET channel from the first PFET channel, the first channel isolation layer disposed directly between the first NFET channel and the first PFET channel along a vertical direction; and a second channel isolation layer separating the second NFET channel from the second PFET channel, the second channel isolation layer disposed directly between the second NFET channel and the second PFET channel along a vertical direction. The S/D isolation layer is separated from the first and second channel isolation layers by inner dielectric spacers. In a further embodiment, the S/D isolation layer has a thickness greater than a thickness of the first and second channel isolation layers.

In an embodiment, the first NFET gate dielectric layer is a gate dielectric layer wrapping around one NFET channel of a first vertical stack of NFET channels, the first PFET gate dielectric layer is a gate dielectric layer wrapping around one PFET channel of a first vertical stack of PFET channels, and the gate metal electrode includes a same metal fill material wrapping around the first NFET gate dielectric layer and the first PFET gate dielectric layer.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of forming a semiconductor device, comprising:
forming a CFET structure having a bottom gate region and a top gate region, the bottom gate region having a first plurality of gate dielectric layers wrapping around a first plurality of channels, the top gate region having a second plurality of gate dielectric layers wrapping around a second plurality of channels;
performing a first dipole loop process to drive first dipole dopants into the first plurality of gate dielectric layers, wherein the first dipole loop process includes iteratively depositing first dipole dopant layers over the first plurality of gate dielectric layers, perform annealing to the first plurality of gate dielectric layers, and removing the first dipole dopant layers, and wherein a first gate dielectric layer of the first plurality of gate dielectric layers is annealed one time and a second gate dielectric layer of the first plurality of gate dielectric layers is annealed two times;
performing a second dipole loop process to drive second dipole dopants into the second plurality of gate dielectric layers, wherein the second dipole loop process includes iteratively depositing second dipole dopant layers over the second plurality of gate dielectric layers, perform annealing to the second plurality of gate dielectric layers, and removing the second dipole dopant layers, and wherein a third gate dielectric layer of the second plurality of gate dielectric layers is annealed one time and a fourth gate dielectric layer of the second plurality of gate dielectric layers is annealed two times; and
after performing the first and second dipole loop processes, depositing a gate metal over the first and second plurality of gate dielectric layers.

2. The method of claim 1, wherein the first dipole dopants include lanthanum, and the second dipole dopants include zinc.

3. The method of claim 1, wherein before performing the annealing to the first plurality of gate dielectric layers, the first dipole loop process further includes:
depositing the first dipole dopant layers over the second plurality of gate dielectric layers;
forming a hard mask over the bottom gate region but leaving the top gate region exposed, wherein the hard mask covers first dipole dopant layers over the first plurality of gate dielectric layers while exposing first dipole dopant layers over the second plurality of gate dielectric layers;
removing the first dipole dopant layers over the second plurality of gate dielectric layers; and
removing the hard mask.

4. The method of claim 1, wherein before performing the annealing to the second plurality of gate dielectric layers, the second dipole loop process further includes:
forming a hard mask over the bottom gate region but leaving the top gate region exposed, the hard mask covers the first plurality of gate dielectric layers while exposing the second plurality of gate dielectric layers;
depositing the second dipole dopant layers over the hard mask when depositing the second dipole dopant layers over the second plurality of gate dielectric layers; and
removing the hard mask.

5. The method of claim 1, further comprising a dipole patterning process, the dipole patterning process includes masking the CFET structure before performing each dipole loop of the first or the second dipole loop processes,
wherein before performing a first dipole loop, the dipole patterning process exposes a first portion of the CFET structure, the first portion includes a first CFET device gate region having the second and the fourth gate dielectric layers,
wherein before performing a second dipole loop, the dipole patterning process exposes a second portion of the CFET structure, second portion includes the first CFET device gate region having the second and the fourth gate dielectric layers and a second CFET device gate region having the first and third gate dielectric layers.

6. The method of claim 5, wherein performing the first or second dipole loop process in combination with the dipole patterning process results in multiple gate threshold voltages in the CFET structure, wherein performing n dipole loops results in (n+1) gate threshold voltages.

7. The method of claim 1, further comprising a dipole patterning process, the dipole patterning process includes masking the CFET structure before performing each dipole loop of the first or the second dipole loop processes,
wherein before performing a first dipole loop, the dipole patterning process exposes a first portion of the CFET structure, the first portion includes a first CFET device gate region having the second and the fourth gate dielectric layers and a second CFET device gate region having the first and third gate dielectric layers,
wherein before performing a second dipole loop, the dipole patterning process exposes a second portion of the CFET structure, the second portion includes the first CFET device gate region having the second and the fourth gate dielectric layers.

8. The method of claim 7, wherein performing the first or second dipole loop process in combination with the dipole patterning process results in multiple gate threshold voltages in the CFET structure, wherein performing n dipole loops results in (2ⁿ) gate threshold voltages.

9. A method of forming a semiconductor device, comprising:
receiving a workpiece having a substrate and a semiconductor stack with interleaved first and second semiconductor layers over the substrate, wherein the first semiconductor layers include a first material, the second semiconductor layers include a second material;
forming dummy gate stacks over channel regions of the semiconductor stack;
forming source/drain (S/D) trenches adjacent to the channel regions, thereby exposing side surfaces of the semiconductor stack;
epitaxially growing first S/D features in the S/D trenches;
forming an S/D isolation layer over the first S/D features;
epitaxially growing second S/D features in the S/D trenches and over the S/D isolation layer;
forming an interlayer dielectric (ILD) layer over the second S/D features;
removing the dummy gate stacks;
forming suspended semiconductor channels by removing the first semiconductor layers;
forming gate dielectric layers over the channel regions and wrapping around each of the suspended semiconductor channels;
performing a first dipole loop process to drive first dipole dopants of various concentrations into a first plurality of the gate dielectric layers;
performing a second dipole loop process to drive second dipole dopants of various concentrations into a second plurality of the gate dielectric layers; and
depositing a gate metal over the first and second plurality of the gate dielectric layers.

10. The method of claim 9, wherein the first dipole loop process includes iteratively performing at least two times:
depositing first dipole dopant layers over the gate dielectric layers, the gate dielectric layers include a first plurality of gate dielectric layers over semiconductor channels for a top device and a second plurality of gate dielectric layers over semiconductor channels for a bottom device;
forming a hard mask over the bottom device but leaving the top device exposed;
removing the first dipole dopant layers over the top device;
removing the hard mask;
annealing to drive the first dipole dopants into the first plurality of gate dielectric layers; and
removing the first dipole dopant layers.

11. The method of claim 10, wherein the second dipole loop process includes iteratively performing at least two times:
forming a hard mask over the bottom device but leaving the top device exposed;
depositing second dipole dopant layers over exposed gate dielectric layers in the top device while the hard mask covers the gate dielectric layers in the bottom device;
removing the hard mask;
annealing to drive the second dipole dopants into the second plurality of gate dielectric layers; and
removing the second dipole dopant layers.

12. A semiconductor device, comprising:
a first CFET having a first n-type field-effect transistor (NFET) and a first p-type field-effect transistor (PFET) directly above or below the first NFET, wherein the first NFET has a first NFET channel and a first NFET gate dielectric layer around the first NFET channel, and the first PFET has a first PFET channel and a first PFET gate dielectric layer around the first PFET channel;
a second CFET having a second NFET and a second PFET directly above or below the second NFET, wherein the second NFET has a second NFET channel and a second NFET gate dielectric layer around the second NFET channel, and the second PFET has a second PFET channel and a second PFET gate dielectric layer around the second PFET channel; and
a gate metal electrode directly on the first and second NFET gate dielectric layers and the first and second PFET gate dielectric layers,
wherein the first and second NFET gate dielectric layers include an n-type dopant, and the first and second PFET gate dielectric layers include a p-type dopant different from the n-type dopant; and
wherein the first NFET gate dielectric layer has a different amount of the n-type dopant from that of the second NFET, and the first PFET gate dielectric layer has a different amount of the p-type dopant than that of the second PFET gate dielectric layer.

13. The semiconductor device of claim 12, wherein the n-type dopant includes lanthanum, and the p-type dopant includes zinc.

14. The semiconductor device of claim 12,
wherein the first NFET gate dielectric layer surrounds a first portion of the gate metal electrode,
wherein the second NFET gate dielectric layer surrounds a second portion of the gate metal electrode,
wherein the first and second portions of the gate metal electrode have substantially the same thickness.

15. The semiconductor device of claim 12,
wherein the first NFET gate dielectric layer surrounds a first portion of the gate metal electrode,
wherein the first PFET gate dielectric layer surrounds a second portion of the gate metal electrode,
wherein the first and second portions of the gate metal electrode have substantially the same thickness.

16. The semiconductor device of claim 12, wherein the first NFET gate dielectric layer is a gate dielectric layer wrapping around one NFET channel of a first vertical stack of NFET channels, and the first NFET gate dielectric layer has a greater amount of the n-type dopant than another NFET gate dielectric layer wrapping around another NFET channel of the first vertical stack of NFET channels.

17. The semiconductor device of claim 12, wherein the first PFET gate dielectric layer is a gate dielectric layer wrapping around one PFET channel of a first vertical stack of PFET channels, and the first PFET gate dielectric layer has a greater amount of the p-type dopant than another PFET gate dielectric layer wrapping around another PFET channel of the first vertical stack of PFET channels.

18. The semiconductor device of claim 12, further comprising:
a first source/drain (S/D) feature disposed between the first NFET channel and the second NFET channel;
a second S/D feature disposed between the first PFET channel and the second PFET channel;
an S/D isolation layer separating the first S/D feature from the second S/D feature, the S/D isolation layer disposed directly between the first and second S/D features along a vertical direction;
a first channel isolation layer separating the first NFET channel from the first PFET channel, the first channel isolation layer disposed directly between the first NFET channel and the first PFET channel along a vertical direction; and
a second channel isolation layer separating the second NFET channel from the second PFET channel, the second channel isolation layer disposed directly between the second NFET channel and the second PFET channel along a vertical direction,
wherein the S/D isolation layer is separated from the first and second channel isolation layers by inner dielectric spacers.

19. The semiconductor device of claim 18, wherein the S/D isolation layer has a thickness greater than a thickness of the first and second channel isolation layers.

20. The semiconductor device of claim 12,
wherein the first NFET gate dielectric layer is a gate dielectric layer wrapping around one NFET channel of a first vertical stack of NFET channels,
wherein the first PFET gate dielectric layer is a gate dielectric layer wrapping around one PFET channel of a first vertical stack of PFET channels,
wherein the gate metal electrode includes a same metal fill material wrapping around the first NFET gate dielectric layer and the first PFET gate dielectric layer.
